(19) United States
(12) Patent Application Publication
(10) Pub. No.: US 2026/0052677 A1
(43) Pub. Date: Feb. 19, 2026

(54) SEMICONDUCTOR DEVICE

(71) Applicant: Samsung Electronics Co., Ltd., Suwon-si (KR)

(72) Inventors: Sunjung LEE, Suwon-si (KR); Sanghyeok YU, Suwon-si (KR); Seungjin JEONG, Suwon-si (KR); Sungnam LYU, Suwon-si (KR); Dosun LEE, Suwon-si (KR); Eulji JEONG, Suwon-si (KR)

(73) Assignee: Samsung Electronics Co., Ltd., Suwon-si (KR)

(21) Appl. No.: 19/197,374

(22) Filed: May 2, 2025

(30) Foreign Application Priority Data
Aug. 14, 2024 (KR) 10-2024-0109224

(51) Int. Cl. H10B 12/00

(52) U.S. Cl. CPC H10B 12/482; H10B 12/315; H10B 12/488; H10B 12/50

(57) ABSTRACT

A semiconductor device may include a bit line extending in a first direction, a first semiconductor vertical portion on the bit line and extending in a vertical direction, a first word line adjacent to the first semiconductor vertical portion, a gate insulating pattern between the first semiconductor vertical portion and the first word line, and a contact pattern on an upper surface of the first semiconductor vertical portion. The vertical direction may be perpendicular to an uppermost surface of the bit line. The upper surface of the first semiconductor vertical portion may be positioned at a lower height than an upper surface of the first word line and an upper surface of the gate insulating pattern. The contact pattern may include metal. A grain size of the metal may be greater than 10 nm and less than 40 nm.

### CROSS-REFERENCE TO RELATED APPLICATIONS

This U.S. non-provisional patent application claims priority under 35 U.S.C. § 119 to Korean Patent Application No. 10-2024-0109224 filed on Aug. 14, 2024, in the Korean Intellectual Property Office, the entire contents of which are hereby incorporated by reference.

### BACKGROUND

Inventive concepts relate to a semiconductor device, and more specifically, relates to a semiconductor device including vertical channel transistors and a method of manufacturing the same.

As a semiconductor device is scaled down, it may be advantageous to develop a fabrication technology capable of increasing an integration density of a semiconductor device and improving an operation speed and a production yield. Thus, semiconductor devices with vertical channel transistors have been suggested to increase an integration density of a semiconductor device and improve resistance and current driving characteristics of the transistor.

### SUMMARY

An aspect of inventive concepts provides a semiconductor device with improved electrical characteristics and/or reliability.

Aspects of inventive concepts are not limited to those mentioned above, and other aspect and/or advantages not mentioned may be clearly understood by those skilled in the art from the description below.

A semiconductor device according to some embodiments of inventive concepts may include a bit line extending in a first direction; a first semiconductor vertical portion on the bit line and extending in a vertical direction, the vertical direction being perpendicular to an uppermost surface of the bit line; a first word line adjacent to the first semiconductor vertical portion; a gate insulating pattern between the first semiconductor vertical portion and the first word line; and a contact pattern on an upper surface of the first semiconductor vertical portion. The upper surface of the first semiconductor vertical portion may be at a lower height than an upper surface of the first word line and an upper surface of the gate insulating pattern. The contact pattern may include metal. A grain size of the metal may be greater than 10 nm and smaller than 40 nm.

A semiconductor device according to some embodiments of inventive concepts may include a bit line extending in a first direction; a first semiconductor vertical portion on the bit line and extending in a vertical direction, the vertical direction being perpendicular to an uppermost surface of the bit line; a first word line adjacent to the first semiconductor vertical portion; a gate insulating pattern between the first semiconductor vertical portion and the first word line; a contact pattern on an upper surface of the first semiconductor vertical portion and extending onto an upper surface of the gate insulating pattern; and a blocking pattern between an upper surface of the first semiconductor vertical portion and the contact pattern. The blocking pattern may extend between the gate insulating pattern and the contact pattern. The upper surface of the first semiconductor vertical portion may be positioned at a higher height than an upper surface of the first word line and at a same height as an upper surface of the gate insulating pattern. The blocking pattern may include an amorphous metal.

A semiconductor device according to some embodiments of inventive concepts may include a bit line extending in a first direction; a semiconductor pattern on the bit line, the semiconductor pattern including a first vertical portion and a second vertical portion spaced apart from each other in the first direction; a first word line and a second word line spaced apart from each other in the first direction between the first vertical portion and the second vertical portion, the first word line and the second word line being adjacent to the first vertical portion and the second vertical portion, respectively; gate insulating patterns between the first vertical portion and the first word line, and the gate insulating patterns being between the second vertical portion and the second word line, respectively; and contact patterns on an upper surface of the first vertical portion and an upper surface of the second vertical portion, respectively. The upper surface of the first vertical portion and the upper surface of the second vertical portion may be positioned at a lower height than an upper surface of the first word line, an upper surface of the second word line, and upper surfaces of the gate insulating patterns. Each of the contact patterns may include a metal. A grain size of the metal may be greater than 10 nm and smaller than 40 nm.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a block diagram of a semiconductor memory device including a semiconductor device according to some embodiments of inventive concepts.

FIG. 2 is a perspective view briefly illustrating a semiconductor device according to some embodiments of inventive concepts.

FIG. 3 is a plan view of a semiconductor device according to some embodiments of inventive concepts.

FIGS. 4 to 6 are cross-sectional views of semiconductor devices according to some embodiments of inventive concepts, which are cross-sectional views corresponding to lines A-A′, B-B′, and C-C′ of FIG. 3, respectively.

FIGS. 7A to 7D are cross-sectional views of semiconductor devices according to some embodiments of inventive concepts, which are cross-sectional views corresponding to lines D-D′ of FIG. 3, respectively.

FIG. 8A is an enlarged view of portion ‘P1’ of FIGS. 7A and 7B.

FIG. 8B is an enlarged view of portion ‘P2’ of FIGS. 7C and 7D.

FIGS. 9A to 16D are cross-sectional views illustrating a method of manufacturing a semiconductor device of FIGS. 4 to 6 and FIG. 7A.

FIG. 16E is an enlarged view of portion ‘P3’ of FIG. 16D.

FIGS. 17A to 17D are cross-sectional views of semiconductor devices according to some embodiments of inventive concepts, each corresponding to a line D-D′ of FIG. 3.

### DETAILED DESCRIPTION

Hereinafter, a semiconductor memory device and/or a manufacturing method thereof according to embodiments of inventive concepts will be described in detail with reference to the drawings.

The notion that elements are “substantially the same” may indicate that the element may be completely the same and may also indicate that the elements may be determined to be the same in consideration of errors or deviations occurring during a process.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

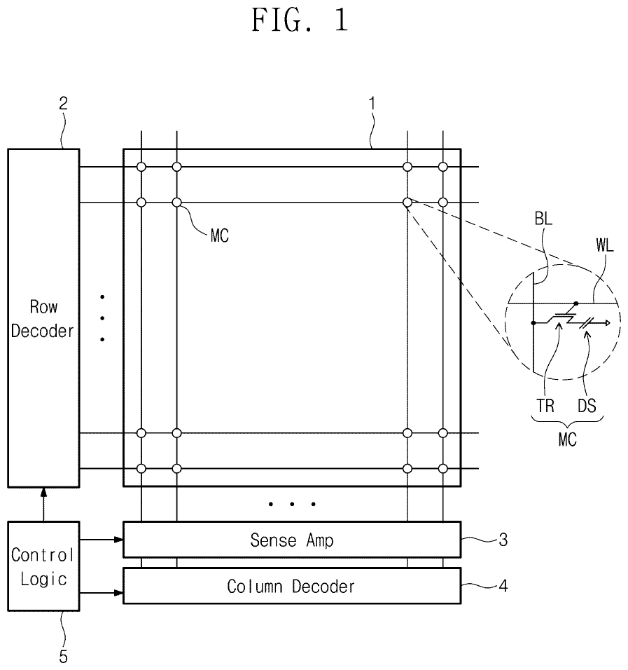

FIG. 1 is a block diagram of a semiconductor memory device including a semiconductor device according to some embodiments of inventive concepts.

Referring to FIG. 1, the semiconductor memory device may include a memory cell array 1, a row decoder 2, a sense amplifier 3, a column decoder 4, and a control logic 5.

The memory cell array 1 may include a plurality of memory cells MC, which may be two- or three-dimensionally disposed. Each of the memory cells MC may be disposed between and connected to a word line WL and a bit line BL crossing each other.

Each of the memory cells MC may include a selection element TR and a data storage element DS, which may be electrically connected to each other in series. The selection element TR may be disposed between and connected to the data storage element DS and the word line WL, and the data storage element DS may be connected to the bit line BL through the selection element TR. The selection element TR may be a field effect transistor (FET), and the data storage element DS may be realized by a capacitor, a magnetic tunnel junction pattern, or a variable resistor. As an example, the selection element TR may include a transistor, a gate electrode of the transistor may be connected to the word line WL, and drain/source terminals of the transistor may be connected to the bit line BL and the data storage element DS, respectively.

The row decoder 2 may be configured to decode address information, which may be input from the outside, and to select one of the word lines WL of the memory cell array 1, based on the decoded address information. The address information decoded by the row decoder 2 may be provided to a row driver (not shown), and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which may be selected based on address information decoded by the column decoder 4, and a reference bit line.

The column decoder 4 may provide a data transmission path between the sense amplifier 3 and an external device (e.g., a memory controller). The column decoder 4 may be configured to decode address information, which is input from the outside, and to select one of the bit lines BL, based on the decoded address information.

The control logic 5 may generate control signals, which may be used to control writing or reading operations on the memory cell array 1.

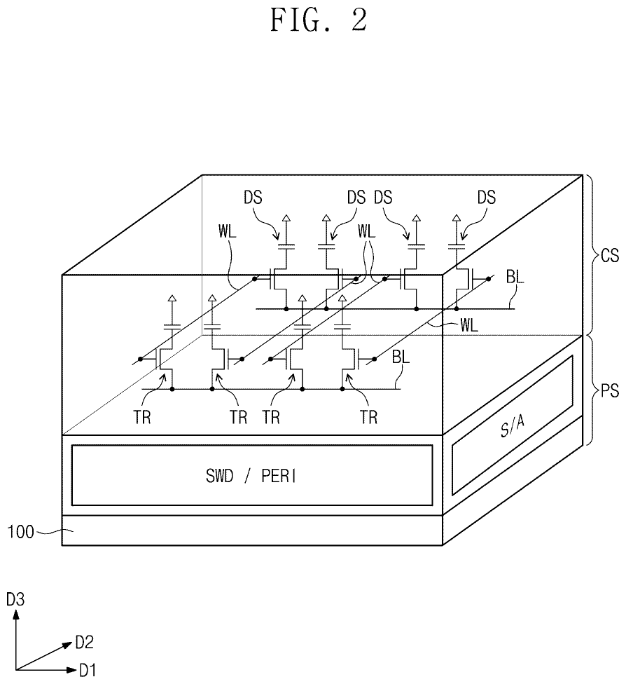

FIG. 2 is a perspective view briefly illustrating a semiconductor device according to some embodiments of inventive concepts.

Referring to FIG. 2, a semiconductor device according to some embodiments of inventive concepts may include a substrate 100, a peripheral circuit structure PS on the substrate 100, and a cell array structure CS on the peripheral circuit structure PS.

The peripheral circuit structure PS may include core and peripheral circuits formed on the substrate 100. The core and peripheral circuits may include the row and column decoders 2 and 4, the sense amplifier 3, and the control logics 5 described with reference to FIG. 1. The peripheral circuit structure PS may be provided between the substrate 100 and the cell array structure CS, in a third direction D3 perpendicular to an upper surface of the substrate 100.

The cell array structure CS may include the bit lines BL, the word lines WL, and the memory cells MC therebetween (e.g., see FIG. 1). The memory cells MC (e.g., see FIG. 1) may be two- or three-dimensionally disposed on a plane that is parallel to the upper surface of the substrate 100 and is extended in two different directions (e.g., first and second directions D1 and D2). Each of the memory cells MC (e.g., see FIG. 1) may include the selection element TR and the data storage element DS, as described above.

According to some embodiments, each of the memory cells MC (e.g., see FIG. 1) may include a vertical channel transistor (VCT), which may be used as the selection element TR. The vertical channel transistor may be configured to include a channel region that is extended in a direction (i.e., the third direction D3) perpendicular to the upper surface of the substrate 100. In addition, each of the memory cells MC (e.g., see FIG. 1) may include a capacitor, which may be used as the data storage element DS.

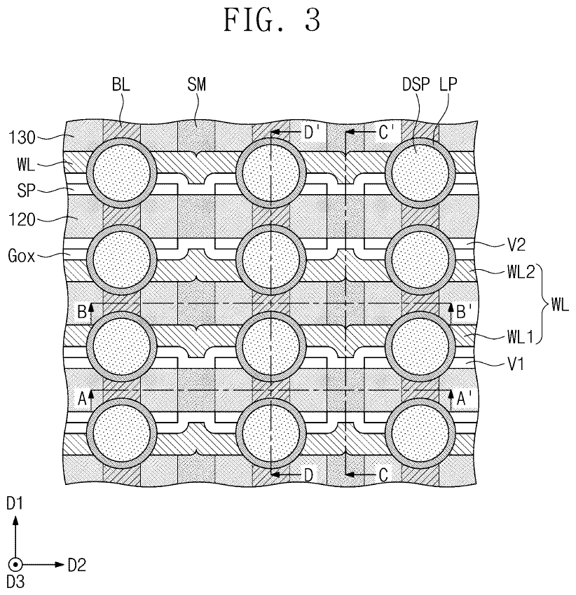

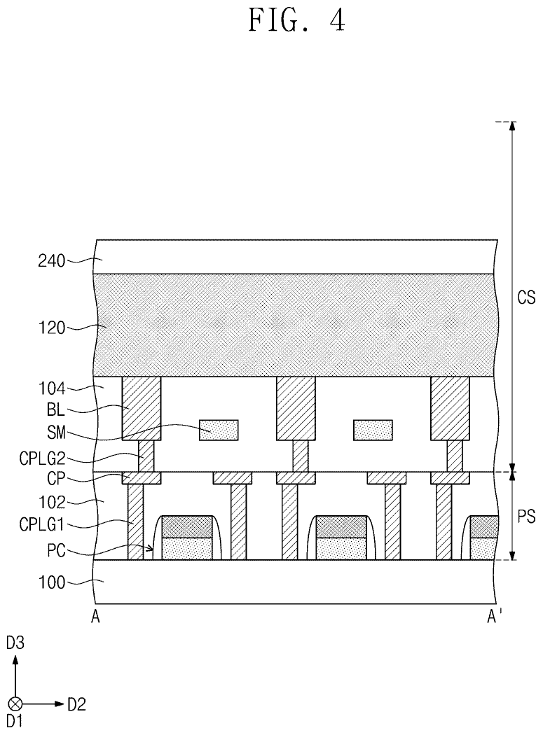

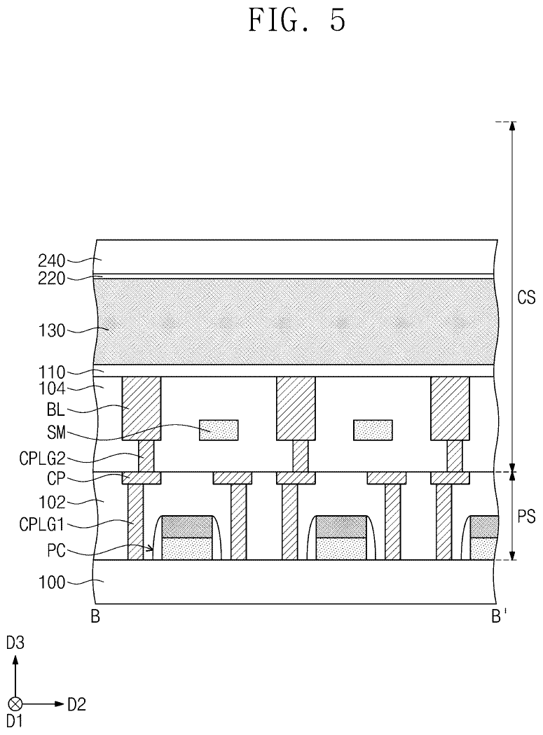

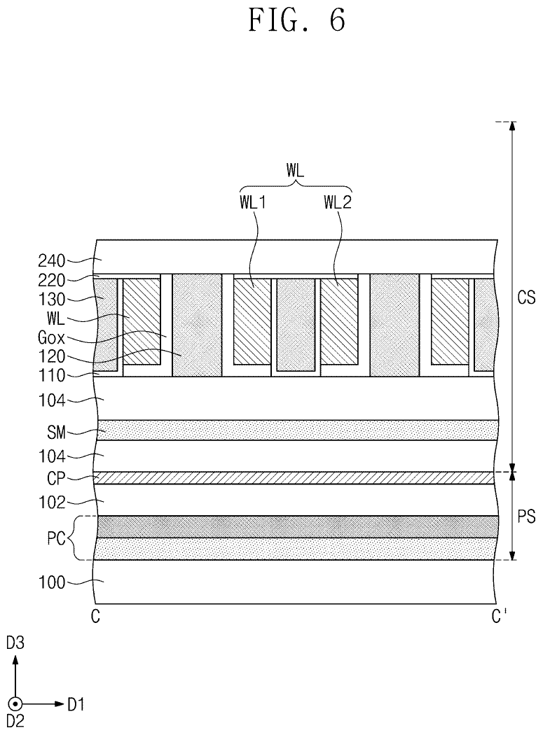

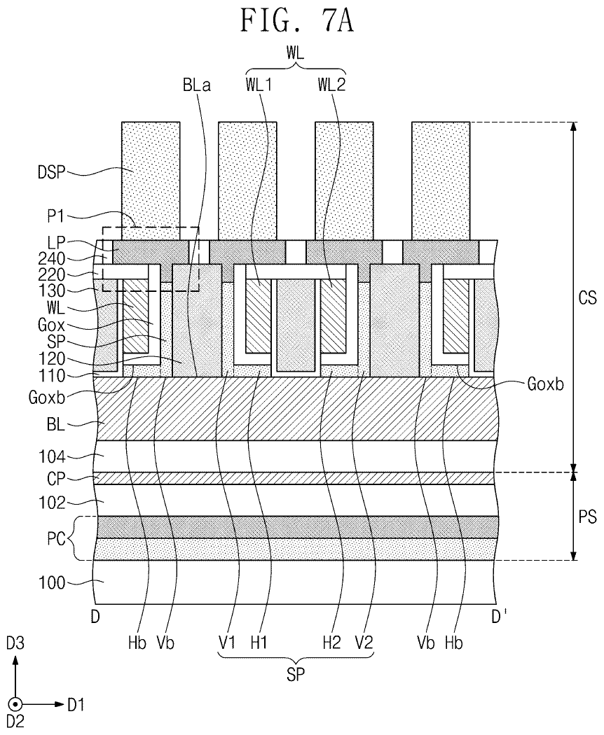

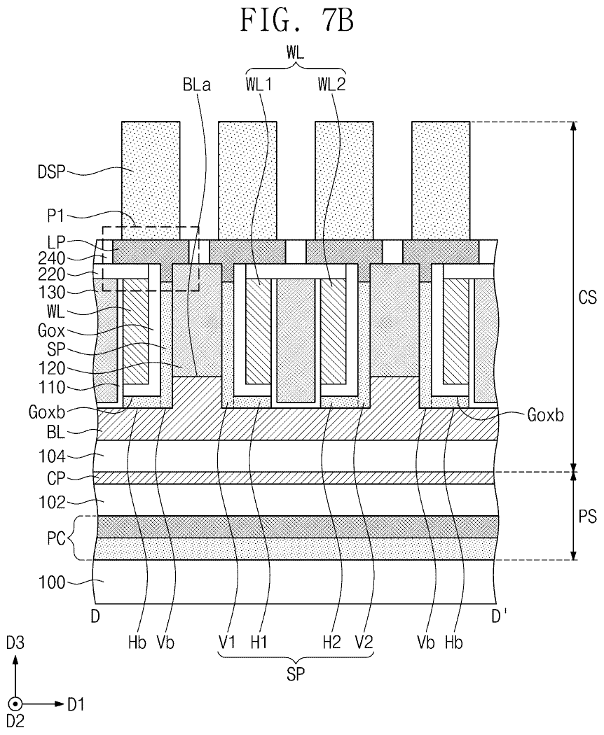

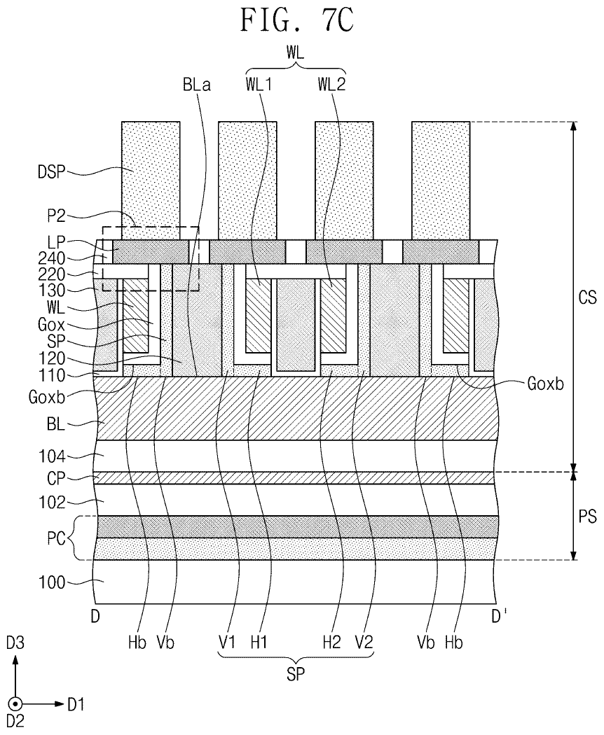

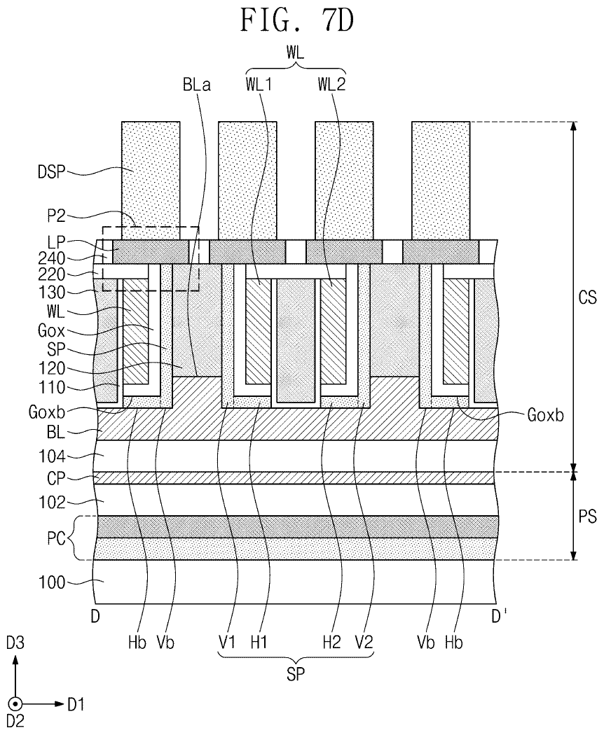

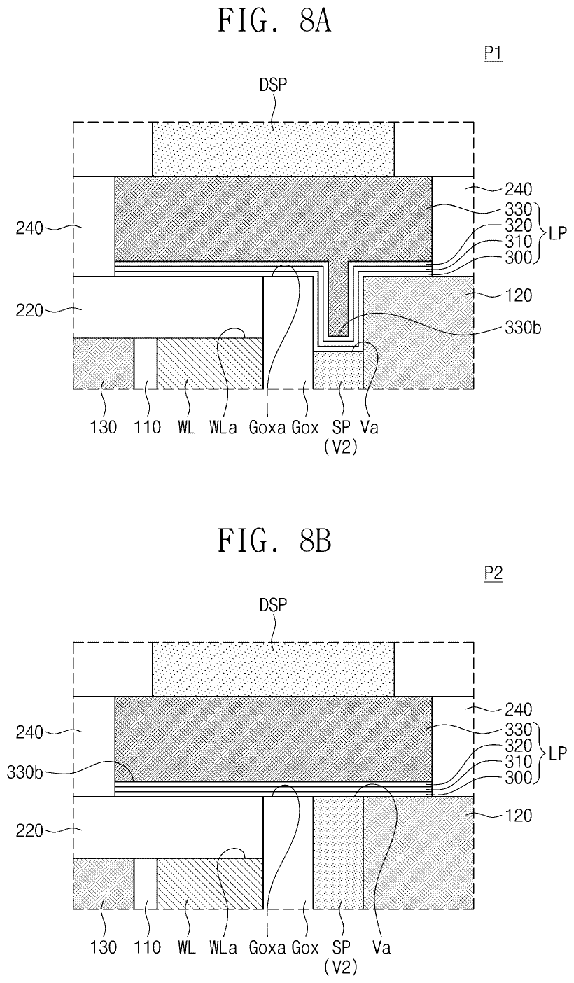

FIG. 3 is a plan view of a semiconductor device according to some embodiments of inventive concepts. FIGS. 4 to 6 are cross-sectional views corresponding to lines A-A′, B-B′, and C-C′ of FIG. 3, respectively. FIGS. 7A and 7B are cross-sectional views corresponding to lines D-D′ of FIG. 3, respectively. FIG. 8A is an enlarged view of portion ‘P1’ of FIGS. 7A and 7B.

Referring to FIGS. 3 to 6, FIGS. 7A, 7B, and 8A, a semiconductor device may include a substrate 100, a peripheral circuit structure PS on the substrate 100, and a cell array structure CS on the peripheral circuit structure PS.

The substrate 100 may be a semiconductor substrate. The substrate 100 may be, for example, a silicon substrate, a germanium substrate, or a silicon-germanium substrate.

The peripheral circuit structure PS may include a peripheral gate structure PC, peripheral contact pads CP, peripheral contact plugs CPLG1 integrated on the substrate 100, and a first interlayer insulating layer 102 covering them. The peripheral gate structure PC may include the sense amplifier 3 of FIG. 1. The cell array structure CS may include memory cells including a vertical channel transistor.

The cell array structure CS may include a plurality of cell contact plugs CPLG2, a plurality of bit lines BL, a plurality of shielding structures SM, a second interlayer insulating layer 104, a plurality of semiconductor patterns SP, a plurality of word lines WL, a plurality of gate insulating patterns Gox, and data storage patterns DSP. The second interlayer insulating layer 104 may cover the cell contact plugs CPLG2 and the shielding structures SM. The gate insulating patterns Gox may include a bottom surface Goxb and the bottom surface Goxb may be on a surface of the plurality of semiconductor patterns SP.

For example, the peripheral gate structures PC of the peripheral circuit structure PS may be electrically connected to the bit lines BL through the peripheral contact plugs CPLG1, the peripheral contact pads CP, and the cell contact plugs CPLG2. Each of the first and second interlayer insulating layers 102 and 104 may include multilayered insulating layers, and may include, for example, at least one of silicon oxide, silicon nitride, silicon oxynitride, and a low-k material. In this specification, the low-k material means a material having a lower dielectric constant than silicon oxide. For example, the low-k material may include a dielectric material having a dielectric constant of 3.9 or less, and may include a material doped with fluorine (F) or carbon (C) in silicon oxide.

The bit line BL may be provided on the substrate 100 in the second interlayer insulating layer 104 and may extend in a first direction D1. The bit line BL may be provided in the plural, and the bit lines BL may be spaced apart from each other in a second direction D2. The bit line BL may be electrically connected to the peripheral contact pad CP through the cell contact plug CPLG2. In the present specification, the first direction D1 and the second direction D2 may be directions that are parallel to an upper surface of the substrate 100 and intersect each other. A third direction D3 may be a vertical direction D3 that is perpendicular to the upper surface of the substrate 100. The first to third directions D1, D2, and D3 may be directions that are orthogonal to each other.

The bit line BL may include, but is not limited to, at least one of doped polysilicon, a metal (e.g., Al, Cu, Ti, Ta, Ru, W, Mo, Pt, Ni, Co), a conductive metal nitride (e.g., TiN, TaN, WN, NbN, TiAIN, TiSiN, TaSiN, RuTiN), a conductive metal silicide or a conductive metal oxide (e.g., PtO, RuO₂, IrO₂, SrRuO₃ (SRO), (Ba,Sr)RuO₃ (BSRO), CaRuO₃ (CRO), LaSrCoO (LSCo). The bit line BL may include a single layer or multiple layers of the aforementioned materials. In some embodiments, the bit line BL may include a two-dimensional semiconductor material, for example, the two-dimensional material may include graphene, carbon nanotubes, or a combination thereof.

The shielding structures SM may be provided between the bit lines BL, respectively, and the shielding structures SM may extend in the first direction D1. The bit lines BL and the shielding structures SM may be spaced apart from each other in the second direction D2 and may be alternately disposed. The shielding structures SM may include a conductive material, such as a metal, for example. The shielding structures SM may be provided in the second interlayer insulating layer 104, and upper surfaces of the shielding structures SM may be positioned at a lower height than uppermost surfaces BLa of the bit lines BL. In the present specification, a height may mean a height in the third direction D3.

For example, the shielding structures SM may be formed of a conductive material and may include an air gap or void therein. In another example, although not shown, air gaps may be provided in the second interlayer insulating layer 104 instead of the shielding structures SM.

The semiconductor pattern SP may be disposed on a bit line BL. A plurality of semiconductor patterns SP may be provided. The semiconductor patterns SP may be spaced apart from each other in first and second directions D1 and D2.

The semiconductor pattern SP may include a first vertical portion V1 and a second vertical portion V2 spaced apart from each other in the first direction D1. The semiconductor pattern SP may include a first horizontal portion H1 extending from a lower portion of the first vertical portion V1 toward the second vertical portion V2. The semiconductor pattern SP may include a second horizontal portion H2 extending from a lower portion of the second vertical portion V2 toward the first vertical portion V1. The first and second horizontal portions H1 and H2 may be spaced apart from each other in the first direction D1. The first vertical portion V1 and the first horizontal portion H1 may be integral with each other, and the second vertical portion V2 and the second horizontal portion H2 may be integral with each other. That is, the first vertical portion V1 and the first horizontal portion H1 may be connected to each other to have an ‘L’-shape, and the second vertical portion V2 and the second horizontal portion H2 may be connected to each other to have a mirror-symmetrical ‘L’-shape. The first vertical portion V1 and the second vertical portion V2 may be referred to as a first semiconductor vertical portion V1 and a second semiconductor vertical portion V2, respectively. The first horizontal portion H1 and the second horizontal portion H2 may be referred to as a first semiconductor horizontal portion H1 and a second semiconductor horizontal portion H2, respectively.

According to some embodiments, as illustrated in FIG. 7A, an upper surface of the bit line BL may extend in a straight line in the first direction D1. A height of an upper surface of the bit line BL may remain the same in the first direction D1. Accordingly, the upper surface of the bit line BL may be the uppermost surface BLa of the bit line BL.

According to another embodiment, as illustrated in FIG. 7B, the upper surface of the bit line BL may have a rough structure. The upper surface of the bit line BL under the semiconductor pattern SP may be disposed at a lower height than the uppermost surface BLa of the bit line BL. The uppermost surface BLa of the bit line BL may be the upper surface disposed at the highest height among the upper surfaces of the bit line BL. The uppermost surface BLa of the bit line BL may not be provided between the first and second vertical portions V1 and V2 of the semiconductor pattern SP. The uppermost surface BLa of the bit line BL may be provided between adjacent semiconductor patterns SP.

According to some embodiments, as illustrated in FIG. 7A, lower surfaces Hb of the first and second horizontal portions H1 and H2 may be positioned at the same height as the uppermost surface BLa of the bit line BL. Lower surfaces Vb of the first and second vertical portions V1 and V2 may be positioned at the same height as the uppermost surface BLa of the bit line BL. The first and second horizontal portions H1 and H2 may not be embedded in the bit line BL. The first and second vertical portions V1 and V2 may not be embedded in the bit line BL. That is, the semiconductor pattern SP may have a form in which it is not embedded in the bit line BL.

In another embodiment, as illustrated in FIG. 7B, the lower surfaces Hb of the first and second horizontal portions H1 and H2 may be positioned at a height lower than the uppermost surface BLa of the bit line BL. At least a portion of the first and second horizontal portions H1 and H2 may be buried in an upper portion of the bit line BL. As an example, upper surfaces of the first and second horizontal portions H1 and H2 may be positioned at a height lower than the uppermost surface BLa of the bit line BL, but is not limited thereto. As another example, although not illustrated, the upper surfaces of the first and second horizontal portions H1 and H2 may be positioned at a height higher than or the same height as the uppermost surface BLa of the bit line BL. The lower surfaces of the first and second vertical portions V1 and V2 may be buried in the upper portion of the bit line BL. The lower surfaces Vb of the first and second vertical portions V1 and V2 may be coplanar with the lower surfaces Hb of the first and second horizontal portions H1 and H2, and may be positioned at a height lower than the uppermost surface BLa of the bit line BL.

The first and second horizontal portions H1 and H2 of the semiconductor pattern SP may include a common source/drain region, and the upper surfaces of the first and second vertical portions V1 and V2 may include first and second source/drain regions, respectively. The first vertical portion V1 may include a first channel region between a common source/drain region and the first source/drain region, and the second vertical portion V2 may include a second channel region between the common source/drain region and the second source/drain region. Each of the first and second vertical portions V1 and V2 may be electrically connected to the bit line BL. That is, the semiconductor device according to inventive concepts may have a structure in which a pair of vertical channel transistors share one bit line BL.

The semiconductor pattern SP may include an oxide semiconductor, and for example, the oxide semiconductor may include at least one of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O and InₓGa_{y}O, but is not limited thereto. As an example, the semiconductor pattern SP may include indium gallium zinc oxide (IGZO). The semiconductor pattern SP may include a single layer or multiple layers of the oxide semiconductor. The semiconductor pattern SP may include an amorphous, crystalline, or polycrystalline oxide semiconductor. In some embodiments, the semiconductor pattern SP may have a band gap energy greater than the band gap energy of silicon. For example, the semiconductor pattern SP may have a band gap energy of about 1.5 eV to 5.6 eV. For example, the semiconductor pattern SP may have optimal channel performance when the semiconductor pattern SP has a band gap energy of about 2.0 eV to 4.0 eV. For example, the semiconductor pattern SP may be polycrystalline or amorphous, but is not limited thereto. In embodiments, the semiconductor pattern SP may include a two-dimensional semiconductor material, for example, the two-dimensional semiconductor material may include graphene, carbon nanotubes, or a combination thereof.

The word line WL may be disposed between the first vertical portion V1 and the second vertical portion V2. A plurality of word lines WL may be provided. The word lines WL may extend in the second direction D2 and may be spaced apart from each other in the first direction D1.

Each of the word lines WL may include a first word line WL1 and a second word line WL2, and the first word line WL1 and the second word line WL2 may be spaced apart from each other in the first direction D1. The first word line WL1 may be disposed on an inner surface of the first vertical portion V1. The inner surface of the first vertical portion V1 may be a side surface of the first vertical portion V1 facing the second vertical portion V2. The second word line WL2 may be disposed on an inner surface of the second vertical portion V2. The inner surface of the second vertical portion V2 may be a side surface of the second vertical portion V2 facing the first vertical portion V1.

The first word line WL1 may be adjacent to the first channel region of the first vertical portion V1 and may control the first channel region. The second word line WL2 may be adjacent to the second channel region of the second vertical portion V2 and may control the second channel region.

According to some embodiments, as illustrated in FIG. 7A, the word line WL and the bit line BL may not be horizontally overlapped.

According to another embodiment, as illustrated in FIG. 7B, a portion of the word line WL may be buried an upper portion of the bit line BL due to unevenness of the bit line BL. As a result, a buried portion of the word line WL may horizontally overlap the bit line BL. Accordingly, the word line WL may be more effectively controlled to a lower portion of each of the first and second channel regions (e.g., to a lower portion of each of the first and second channel regions provided at a height lower than the uppermost surface BLa of the bit line BL), and as a result, electrical characteristics and/or reliability of the semiconductor device may be improved.

The word line WL may include, but is not limited to, at least one of doped polysilicon, a metal (e.g., Al, Cu, Ti, Ta, Ru, W, Mo, Pt, Ni, Co), a conductive metal nitride (e.g., TiN, TaN, WN, NbN, TiAIN, TiSiN, TaSIN, RuTiN), a conductive metal silicide, or a conductive metal oxide (e.g., PtO, RuO₂, IrO₂, SrRuO₃ (SRO), (Ba,Sr)RuO₃ (BSRO), CaRuO₃ (CRO), LaSrCoO (LSCo). The word line WL may include a single layer or multiple layers of the aforementioned materials. In some embodiments, the word line WL may include a two-dimensional semiconductor material, for example, the two-dimensional semiconductor material may include graphene, carbon nanotubes, or a combination thereof.

The gate insulating pattern Gox may be interposed between the semiconductor pattern SP and the word line WL. Specifically, the gate insulating patterns Gox may be interposed between the inner surface of the first vertical portion V1 and the first word line WL1, and between the inner surface of the second vertical portion V2 and the second word line WL2, respectively. The gate insulating patterns Gox may further extend between the first horizontal portion H1 and the first word line WL1, and between the second horizontal portion H2 and the second word line WL2, respectively. The word line WL may be separated from the semiconductor pattern SP by gate insulating patterns Gox. The gate insulating pattern Gox may cover the semiconductor pattern SP with a uniform thickness.

The gate insulating pattern Gox may include at least one of silicon oxide, silicon oxynitride, and a high-k dielectric material having a higher dielectric constant than silicon oxide. The high-k dielectric material may include a metal oxide or a metal oxynitride. For example, the high-k dielectric material usable as the gate insulating pattern Gox may include at least one of HfO₂, HfSiO, HfSiON, HfTaO, HfTIO, HfZrO, ZrO₂, and Al₂O₃, but is not limited thereto.

A first insulating pattern 120 may be interposed between the semiconductor patterns SP adjacent to each other in the first direction D1. The first insulating pattern 120 may be provided in the plural. The first insulating patterns 120 may extend in the second direction D2 across the bit line BL and may be spaced apart from each other in the first direction D1. The first insulating pattern 120 may cover at least a portion of outer surfaces of the first and second vertical portions V1 and V2. For example, the first insulating pattern 120 may include at least one of silicon oxide, silicon nitride, silicon oxynitride, and a low-k material. For example, the first insulating pattern 120 may be formed of a single layer or multiple layers.

According to some embodiments, as illustrated in FIG. 7A, the first insulating pattern 120 may cover the outer surfaces of the first and second vertical portions V1 and V2. The lower surfaces Hb of the first and second horizontal portions H1 and H2 of the semiconductor pattern SP may be positioned at the same height as the lower surface of the first insulating pattern 120 and may be coplanar therewith.

According to another embodiment, as illustrated in FIG. 7B, the first insulating pattern 120 may be in contact the uppermost surface BLa of the bit line BL. The first insulating pattern 120 may cover a portion of the outer surfaces of the first and second vertical portions V1 and V2 that is not buried by the bit line BL. The lower surfaces Hb of the first and second horizontal portions H1 and H2 of the semiconductor pattern SP may be positioned at a lower height than the lowermost surface of the first insulating pattern 120.

A second insulating pattern 130 may be disposed between the first word line WL1 and the second word line WL2 of the word line WL. The second insulating pattern 130 may be provided in the plural. The second insulating patterns 130 may extend across the bit line BL in the second direction D2 and may be spaced apart from each other in the first direction D1. The first and second insulating patterns 120 and 130 may be disposed alternately with respect to the first direction D1. The second insulating pattern 130 may include, for example, at least one of silicon oxide, silicon nitride, silicon oxynitride, and a low-k material.

A protection pattern 110 may be interposed between the word line WL and the second insulating pattern 130. The protection pattern 110 may cover an inner surface of the word line WL. The protection pattern 110 may include, for example, at least one of silicon oxide, silicon nitride, and silicon oxynitride.

A capping pattern 220 may be provided on an upper surface WLa of the word line WL. The capping pattern 220 may cover upper surfaces of the protection pattern 110 and the second insulating pattern 130. The capping pattern 220 may extend in the second direction D2. An upper surface of the capping pattern 220 may be coplanar with an upper surface Goxa of the gate insulating pattern Gox. The capping pattern 220 may include, for example, at least one of silicon oxide, silicon nitride, and silicon oxynitride.

Landing pads LP may be disposed on the first and second vertical portions V1 and V2 of the semiconductor pattern SP, respectively. The landing pads LP may be in direct contact with the upper surfaces Vb of the first and second vertical portions V1 and V2 and may be electrically connected. When viewed in a plan view, the landing pads LP may be spaced apart from each other in the first and second directions D1 and D2 and may be disposed in various shapes, such as a matrix shape, a zigzag shape, a honeycomb shape, etc. When viewed in a plan view, each of the landing pads LP may have various shapes, such as a circle, an oval, a rectangle, a square, a rhombus, a hexagon, etc.

For example, referring to FIG. 8A, an upper surfaces Va of the first and second vertical portions V1 and V2 may be disposed at a lower height than the upper surface Goxa of the gate insulating pattern Gox. In addition, the upper surfaces Va of the first and second vertical portions V1 and V2 may be positioned at a lower height than the upper surface WLa of the word line WL. The upper surface Goxa of the gate insulating pattern Gox, an upper surface of the first insulating pattern 120, and an upper surface of the capping pattern 220 may be positioned at the same height and may be coplanar therewith.

The landing pad LP may include a base pattern 300, a blocking pattern 310, a barrier pattern 320, and a contact pattern 330. The base pattern 300 may be disposed on the upper surface Va of each of the first and second vertical portions V1 and V2. The base pattern 300 may extend onto side surface and the upper surface Gox of the gate insulating pattern Gox. The base pattern 300 may extend onto side surface and upper surface of the first insulating pattern 120. The base pattern 300 may extend onto upper surface of the capping pattern 220. That is, the base pattern 300 may conformally cover the upper surface Va of each of the first and second vertical portions V1 and V2, the side surface and upper surface of the gate insulating pattern Gox, the side surface and upper surface of the first insulating pattern 120, and the upper surface of the capping pattern 220. The base pattern 300 may be interposed between the gate insulating pattern Gox, the upper surface Va of each of the first and second vertical portions V1 and V2, and the first insulating pattern 120 and the contact pattern 330 described below. The base pattern 300 may include a first metal, and the first metal may be, for example, Mo, Ni, Au, Pt, Ru, or a combination thereof, but is not limited thereto.

The blocking pattern 310 may be disposed on the base pattern 300. The blocking pattern 310 may conformally cover the base pattern 300. The blocking pattern 310 may vertically overlap the base pattern 300. The blocking pattern 310 may be interposed between the base pattern 300 and a contact pattern 330 described below. The blocking pattern 310 may include an amorphous metal, and may include, for example, amorphous Ti.

The barrier pattern 320 may be disposed on the blocking pattern 310. The barrier pattern 320 may conformally cover the blocking pattern 310. The barrier pattern 320 may be vertically overlapped with the blocking pattern 310. The barrier pattern 320 may be interposed between the blocking pattern 310 and the contact pattern 330 described below. The barrier pattern 320 may include a conductive metal nitride and may include the same metal element as the blocking pattern 310. The barrier pattern 320 may include, for example, TiN, TiSiN, etc., but is not limited thereto.

The contact pattern 330 may be disposed on the barrier pattern 320. The contact pattern 330 may cover an upper surface and a side surface of the barrier pattern 320. The lowermost surface 330b of the contact pattern 330 may be the lowermost surface disposed at the lowest height among lower surfaces of the contact pattern 330. For example, the lowermost surface 330b of the contact pattern 330 may be disposed at a height lower than the upper surface WLa of the word line WL, but is not limited thereto. When viewed in a plan view, the lowermost surface 330b of the contact pattern 330 may be provided in an region vertically overlapping the first and second vertical portions V1 and V2. The contact pattern 330 may include a second metal, and the second metal may be different from the first metal. The contact pattern 330 may include a different metal element from the blocking pattern 310 and the barrier pattern 320. A grain size of the second metal of the contact pattern 330 may be larger than 10 nm and smaller than 40 nm. For example, the second metal may include W, and a grain size of W in the contact pattern 330 may be greater than 10 nm and less than 40 nm.

Accordingly, a portion of the landing pad LP may horizontally overlap the word line WL.

Referring again to FIGS. 3 to 6, FIGS. 7A and 7B, a third interlayer insulating layer 240 may fill a space between the landing pads LP on the first and second insulating patterns 120 and 130. The third interlayer insulating layer 240 may include, for example, at least one of silicon oxide, silicon nitride, and silicon oxynitride, and may include a single layer or multiple layers.

The data storage patterns DSP may be provided on each of the landing pads LP. The data storage patterns DSP may be electrically connected to the first and second vertical portions V1 and V2 of the semiconductor pattern SP respectively via the landing pads LP.

In one example, the data storage patterns DSP may be capacitors and may include lower and upper electrodes, and a capacitor dielectric layer interposed therebetween. In this case, the lower electrode may be in contact with the landing pad LP, and the lower electrode may have various shapes, such as circular, oval, rectangular, square, rhombus, or hexagonal, in a planar view.

Alternatively, the data storage patterns DSP may be variable resistance patterns that may be switched between two resistance states by an electrical pulse applied to the memory element. For example, the data storage patterns DSP may include phase-change materials, perovskite compounds, transition metal oxides, magnetic materials, ferromagnetic materials, or antiferromagnetic materials whose crystal state changes depending on the amount of current.

FIGS. 7C and 7D are cross-sectional views corresponding to the D-D′ line of FIG. 3, respectively. FIG. 8B is an enlarged view of portion ‘P2’ of FIGS. 7C and 7D. For simplicity of explanation, the overlapping content described above is omitted.

Referring to FIGS. 7C, 7D and 8B, the upper surfaces Va of the first and second vertical portions V1 and V2 may be positioned at the same height as the upper surface Goxa of the gate insulating pattern Gox, and may be coplanar therewith. In addition, the upper surfaces Va of the first and second vertical portions V1 and V2 may be positioned at a higher height than the upper surface WLa of the word line WL.

The landing pad LP may include a base pattern 300, a blocking pattern 310, a barrier pattern 320, and a contact pattern 330 that are sequentially stacked. The base pattern 300 may be disposed on the upper surface Va of each of the first and second vertical portions V1 and V2, and may extend onto the upper surface of the gate insulating pattern Gox, the upper surface of the first insulating pattern 120, and the upper surface of the capping pattern 220.

The blocking pattern 310 may be disposed on the base pattern 300 and may conformally cover the base pattern 300. The barrier pattern 320 may be disposed on the blocking pattern 310 and may conformally cover the blocking pattern 310.

The contact pattern 330 may be disposed on the barrier pattern 320. A height of the lower surface of the contact pattern 330 may be maintained the same even when moving in the first and second directions D1 and D2. That is, the lower surface of the contact pattern 330 may be the lowermost surface 330b of the contact pattern 330.

Accordingly, the landing pad LP may not horizontally overlap the word line WL.

The base pattern 300, the blocking pattern 310, the barrier pattern 320, and the contact pattern 330 may include substantially the same material as described with reference to FIG. 8A. In particular, the contact pattern 330 may include W having a grain size greater than 10 nm and smaller than 40 nm.

According to inventive concepts, the contact pattern 330 may include the second metal having the small grain size, thereby limiting and/or suppressing diffusion of hydrogen. In addition, the amorphous metal included in the blocking pattern may have high solubility in hydrogen, and thus hydrogen capture effect may be added. The amorphous metal in the blocking pattern 310 may have a higher solubility in hydrogen than a solubility in hydrogen of the metal nitride in the barrier pattern 320. In particular, as the conductive metal nitride included in the barrier pattern 320 has a columnar structure, hydrogen may diffuse, but as the blocking pattern 310 includes an amorphous metal, the hydrogen diffusion may be limited and/or suppressed due to the effect of blocking the columnar structure of the barrier pattern 320. In addition, as an example, when the barrier pattern 320 includes TiSiN, the hydrogen blocking effect may be exerted more significantly as a ratio of Si is relatively higher. In addition, the base pattern 300 may lower a contact resistance with the channel. As a result, the diffusion of hydrogen into the channel region may be limited and/or suppressed and the contact resistance with the channel may be reduced, thereby improving electrical characteristics and/or reliability of the semiconductor device.

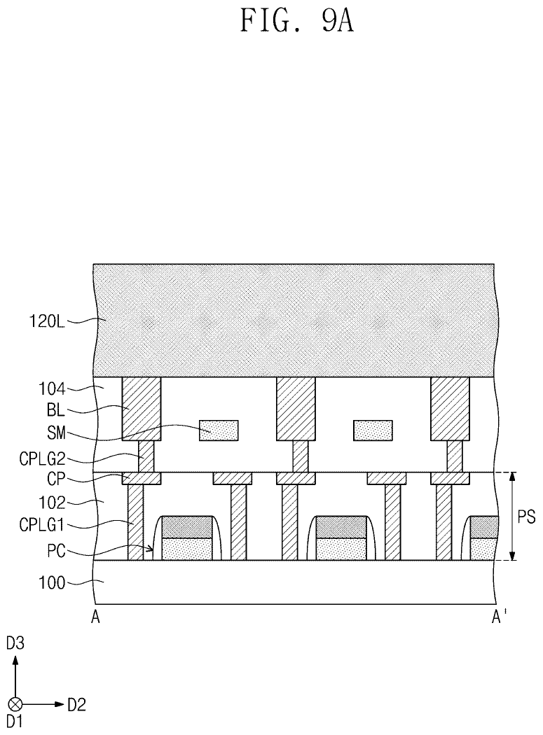

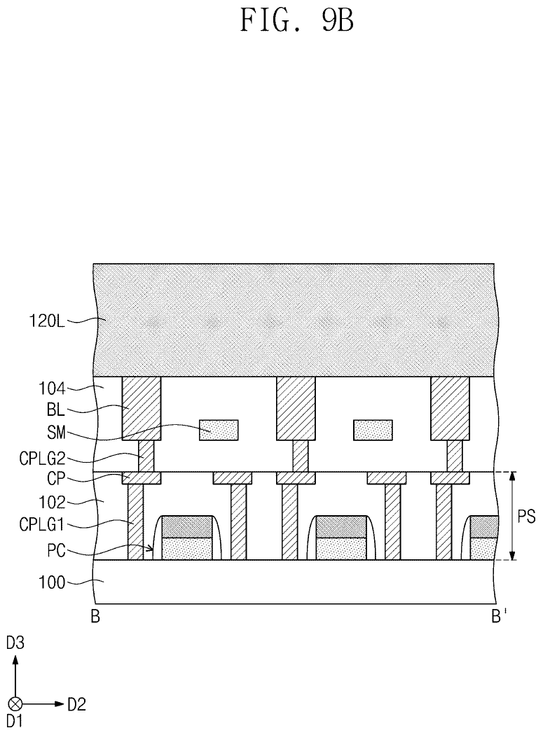

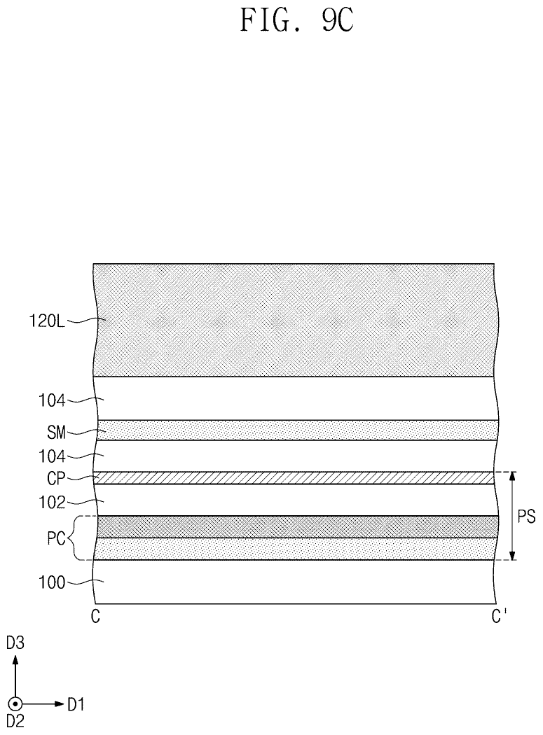

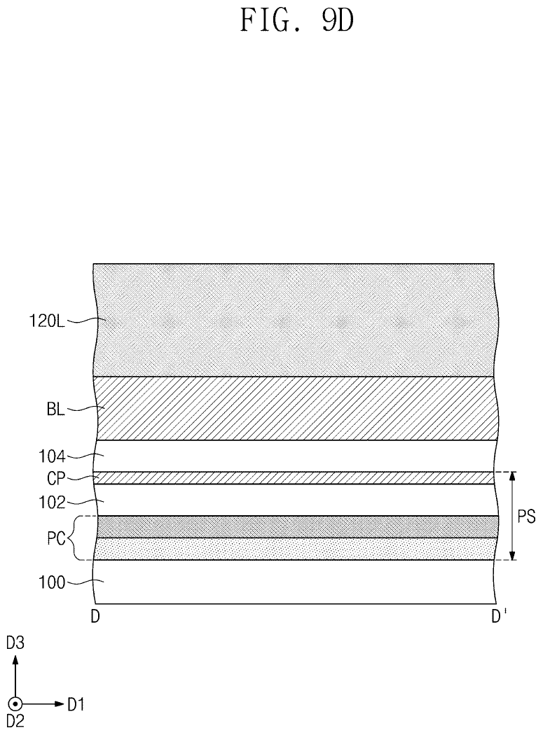

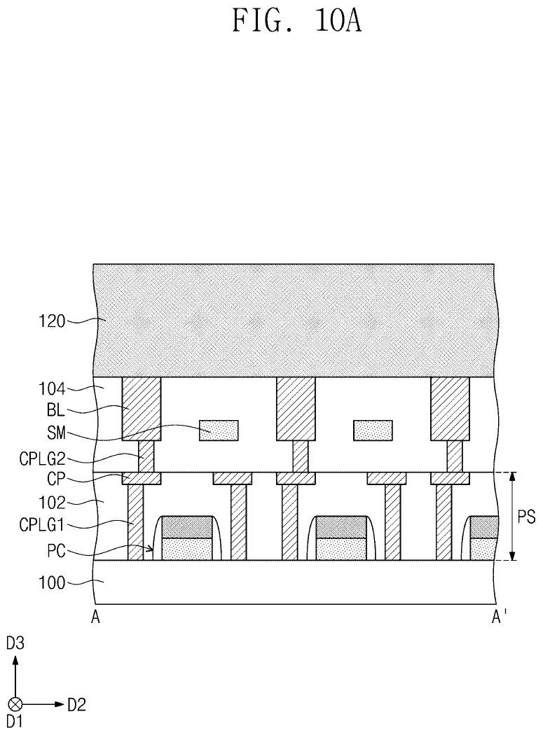

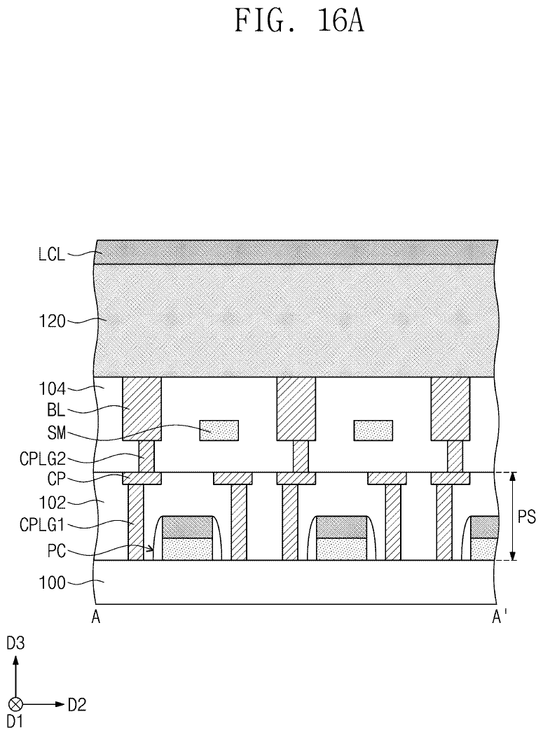

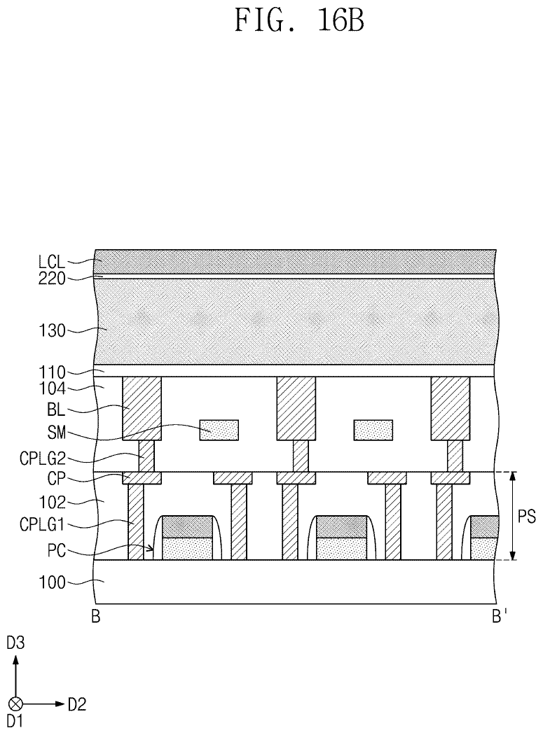

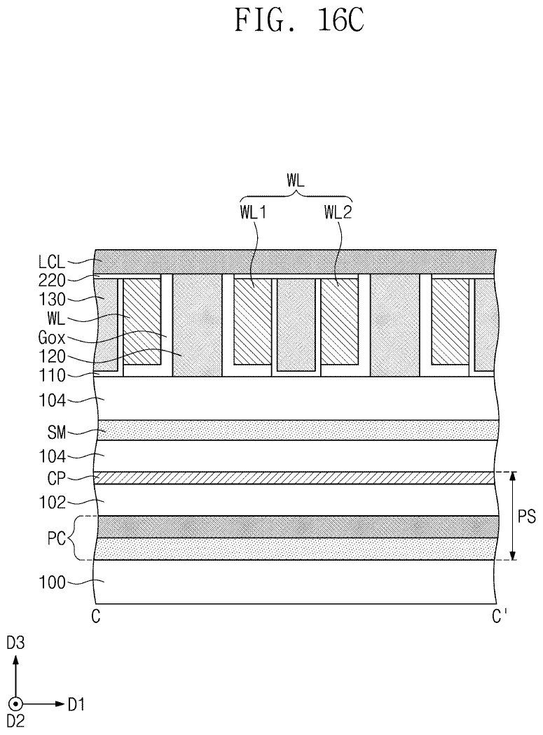

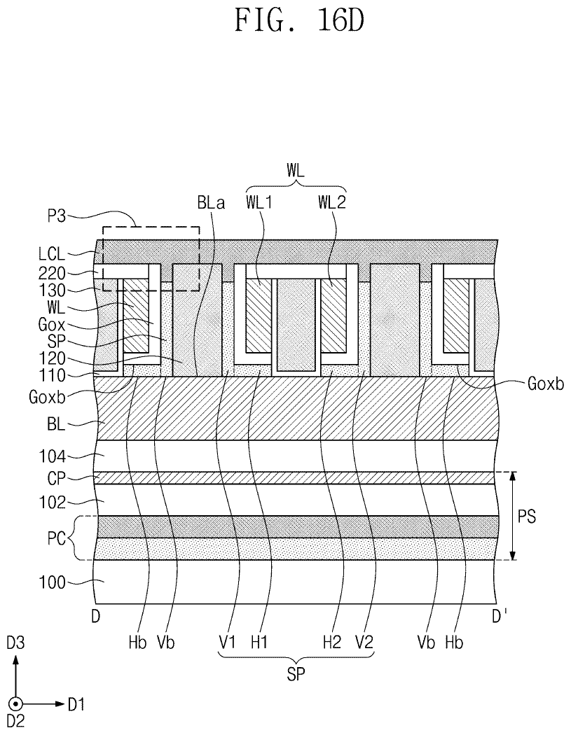

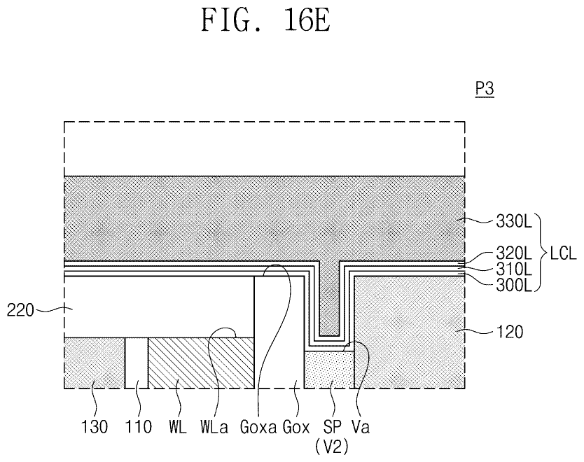

FIGS. 9A to 16D are cross-sectional views illustrating a method of manufacturing the semiconductor device of FIGS. 3 to 6 and FIG. 7A. Specifically, FIGS. 9A, 10A, 11A, 12A, 13A, 14A, 15A, and 16A are cross-sectional views corresponding to line A-A′ of FIG. 3. FIGS. 9B, 10B, 11B, 12B, 13B, 14B, 15B, and 16B are cross-sectional views corresponding to line B-B′ of FIG. 3. FIGS. 9C, 10C, 11C, 12C, 13C, 14C, 15C, and 16C are cross-sectional views corresponding to line C-C′ of FIG. 3. FIGS. 9D, 10D, 11D, 12D, 13D, 14D, 15D, and 16D are cross-sectional views corresponding to line D-D′ of FIG. 3. FIG. 16E is an enlarged view of portion ‘P3’ of FIG. 16D. Hereinafter, a method for manufacturing a semiconductor device of FIG. 7A will be described with reference to FIG. 3 and FIG. 9A to FIG. 16D. To simplify the description, descriptions of contents that overlap the above contents will be omitted.

Referring to FIG. 3 and FIGS. 9A to 9D, a peripheral circuit structure PS may be formed on a substrate 100. Forming the peripheral circuit structure PS may include forming a peripheral gate structure PC, peripheral contact pads CP, peripheral contact plugs CPLG1, and a first interlayer insulating layer 102 covering them. A second interlayer insulating layer 104 may be formed on the peripheral circuit structure PS. A bit line BL may be formed in the second interlayer insulating layer 104. The bit line BL may be formed in the plural. The bit lines BL may be formed to extend in a first direction D1 and be spaced apart from each other in a second direction D2. The bit line BL may be formed to be electrically connected to wirings therebelow and wirings in the peripheral circuit structure PS. Forming the bit line BL may include depositing a bit line layer (not shown) and patterning the bit line layer to form the bit line BL. A shielding structure SM may be formed in the second interlayer insulating layer 104. The shielding structures SM may be formed in the plural. Forming the shielding structures SM may include depositing a shielding layer (not shown) and patterning the shielding layer to form the shielding structures SM.

A first insulating layer 120L may be formed on the second interlayer insulating layer 104 and the bit line BL. The first insulating layer 120L may entirely cover the second interlayer insulating layer 104 and the bit line BL. That is, the first insulating layer 120L may cover the entire front surface of the substrate 100. The first insulating layer 120L may include, for example, at least one of silicon oxide, silicon nitride, silicon oxynitride, and a low-k material.

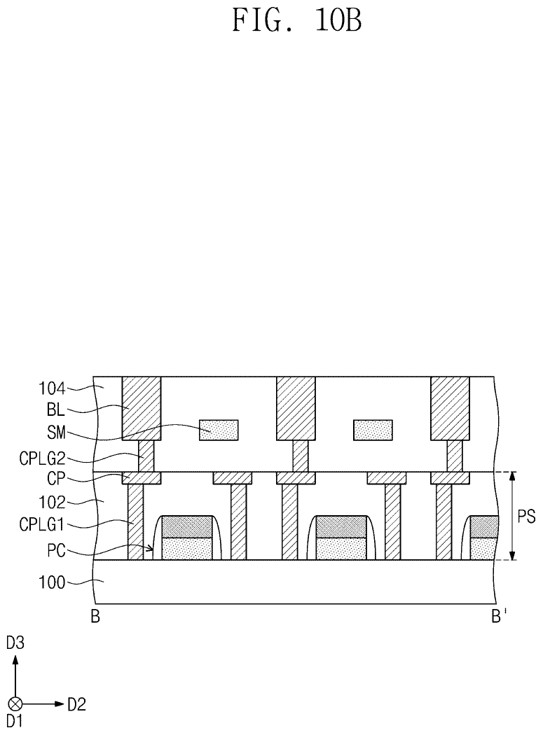

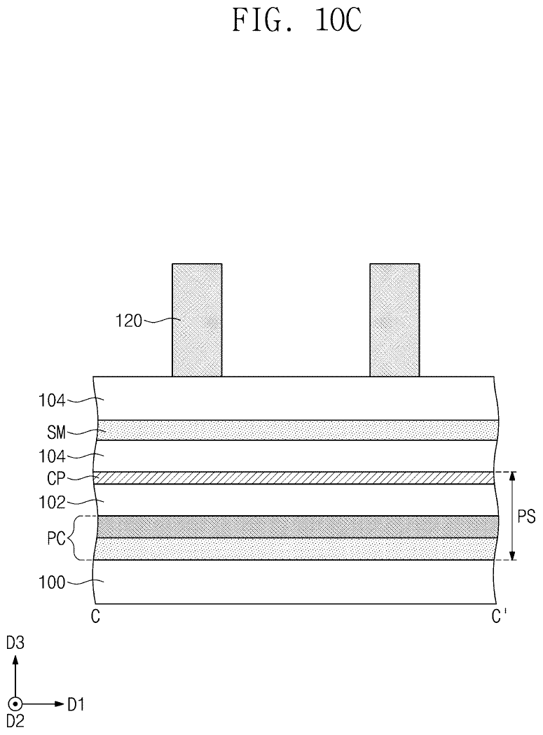

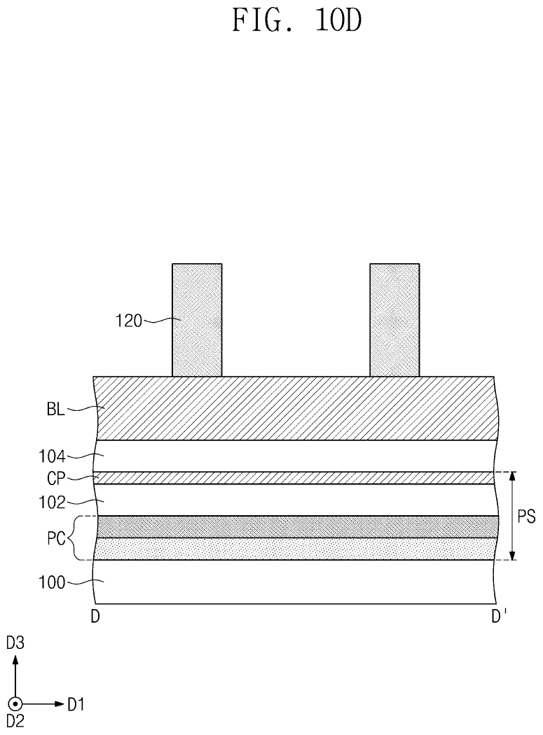

Referring to FIG. 3 and FIG. 10A to FIG. 10D, a first insulating pattern 120 may be formed. Forming the first insulating pattern 120 may include forming a mask pattern (not shown) on the first insulating layer 120L, etching the first insulating layer 120L using the mask pattern as an etching mask, and removing the mask pattern. In the etching process, the bit line BL and the second interlayer insulating layer 104 may not be etched. The first insulating pattern 120 may be formed in the plural. The first insulating patterns 120 may extend in the second direction D2 and be spaced apart from each other in the first direction D1.

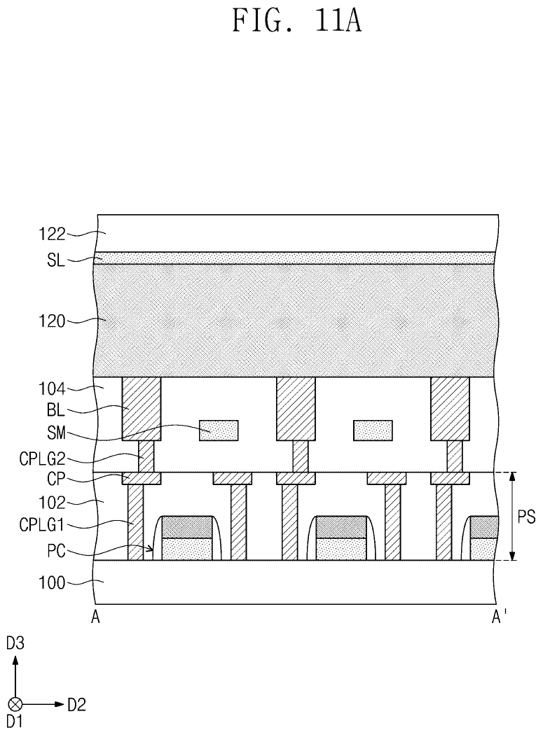

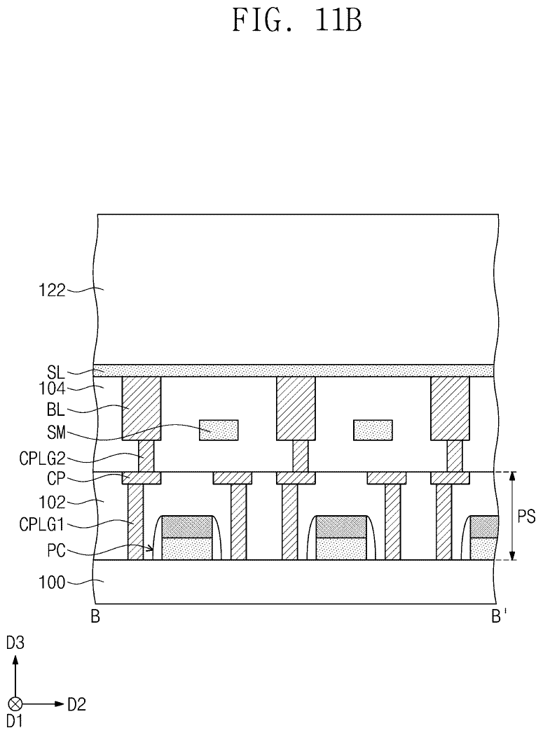

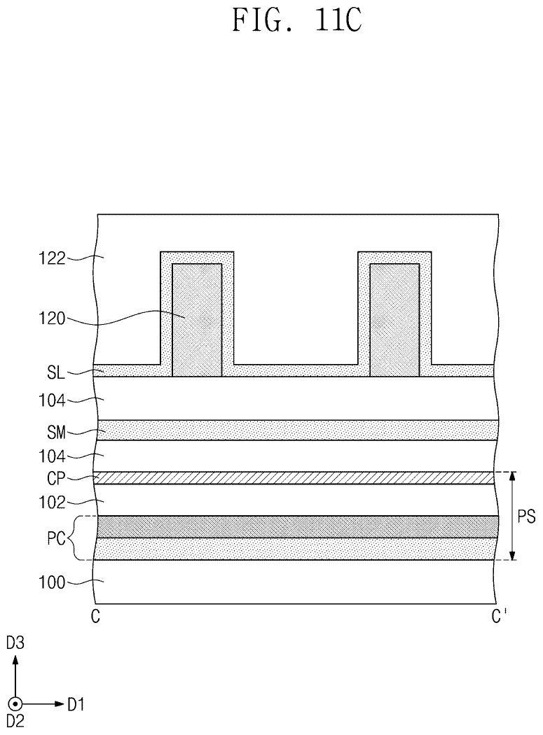

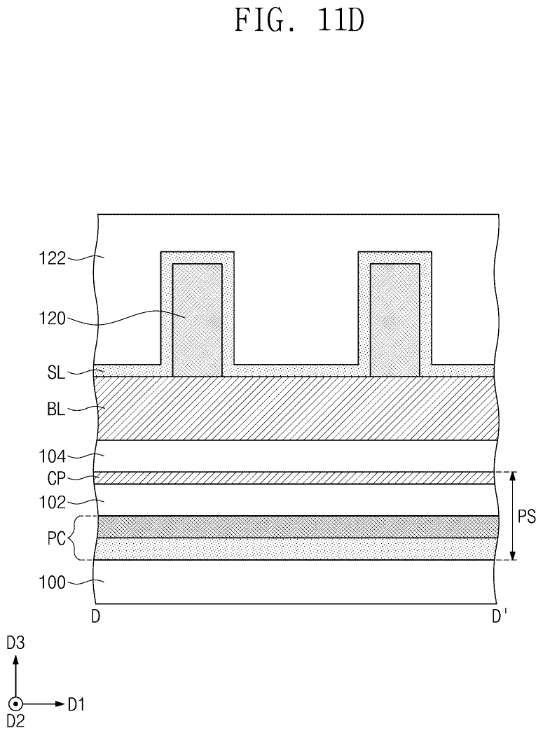

Referring to FIG. 3 and FIGS. 11A to 11D, a semiconductor layer SL and a first mold layer 122 may be sequentially formed on the entire surface of the substrate 100. The semiconductor layer SL and the first mold layer 122 may be formed using a layer-forming technique such as chemical vapor deposition (CVD), physical vapor deposition (PVD), atomic layer deposition (ALD), etc. The semiconductor layer SL may conformally cover the first insulating pattern 120 and may extend to an upper surface of the second interlayer insulating layer 104. The first mold layer 122 may entirely cover the semiconductor layer SL.

The first mold layer 122 may include a material including carbon. For example, the first mold layer 122 may include a spin-on hardmask (SOH) and an amorphous carbon layer (ACL).

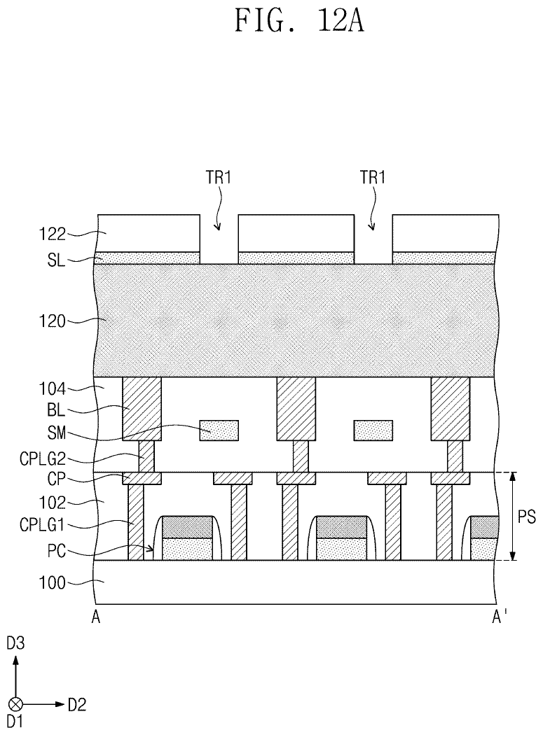

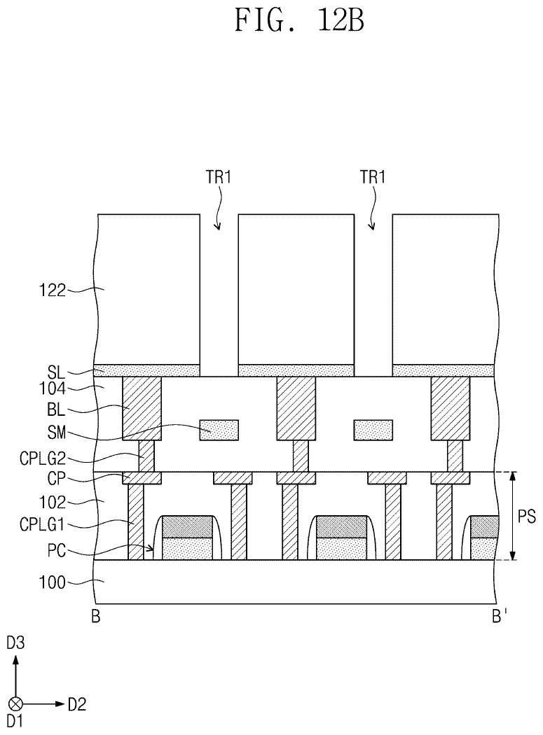

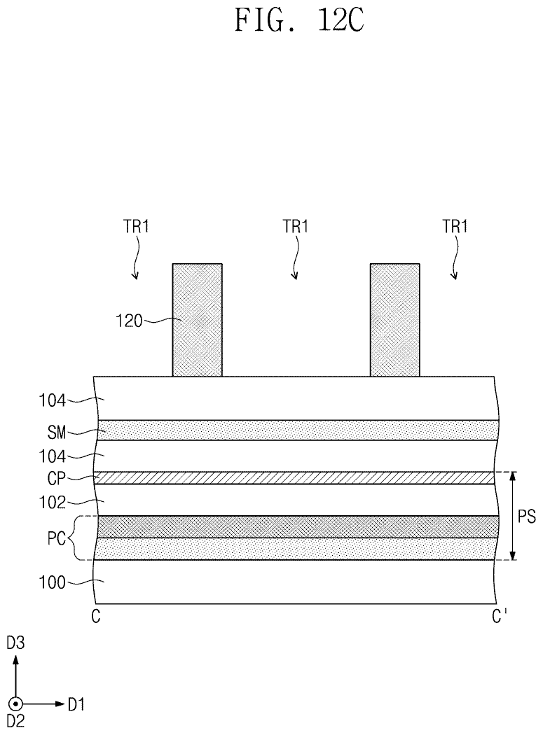

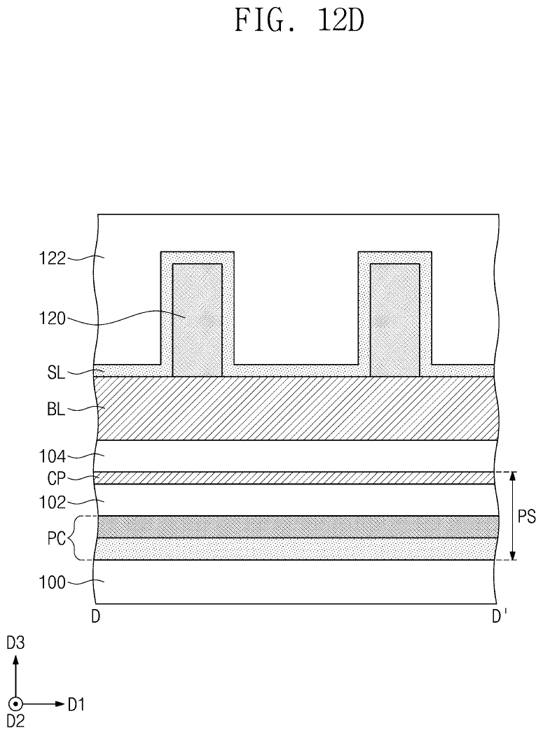

Referring to FIG. 3 and FIGS. 12A to 12D, a first trench TR1 may be formed. Forming the first trench TR1 may include forming a mask pattern (not shown) on a first mold layer 122, sequentially etching the first mold layer 122 and the semiconductor layer SL using the mask pattern as an etching mask, and removing the mask pattern. The etching process may include an anisotropic etching process. In the etching process, the second interlayer insulating layer 104 and the first insulating pattern 120 may not be etched. When viewed in a plan view, the first trench TR1 may be formed in an region that does not vertically overlap the bit line BL. The first trench TR1 may be formed in the plural. The first trenches TR1 may extend in the first direction D1 and may be spaced apart from each other in the second direction D2.

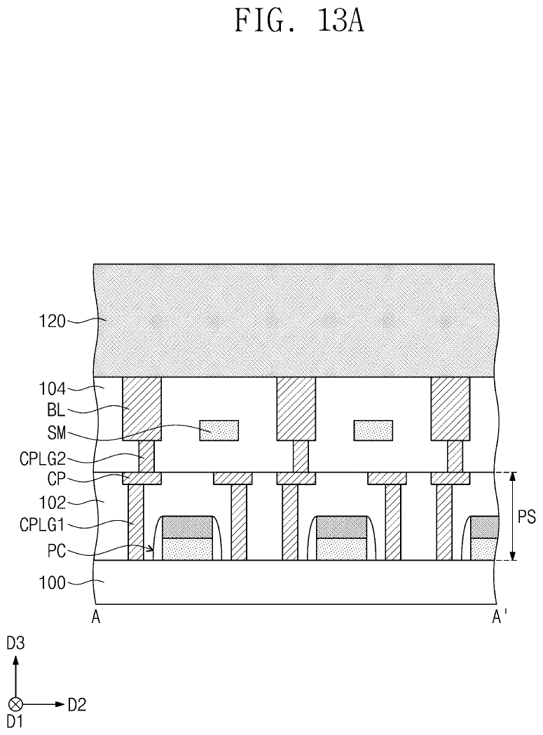

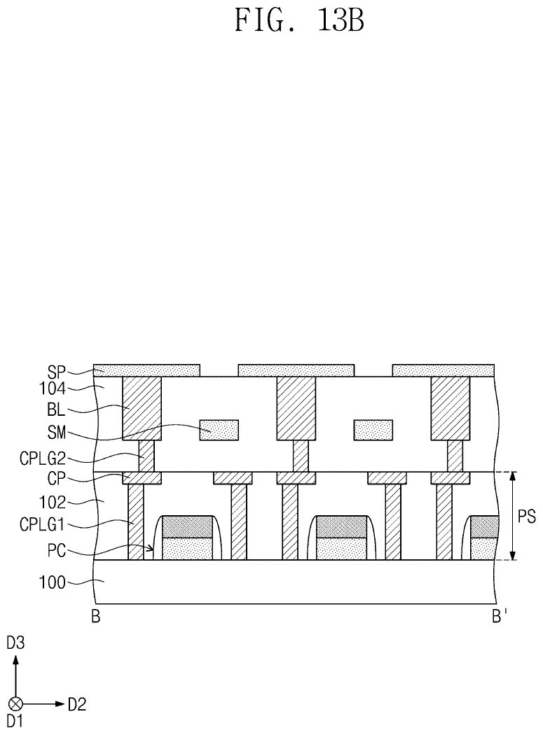

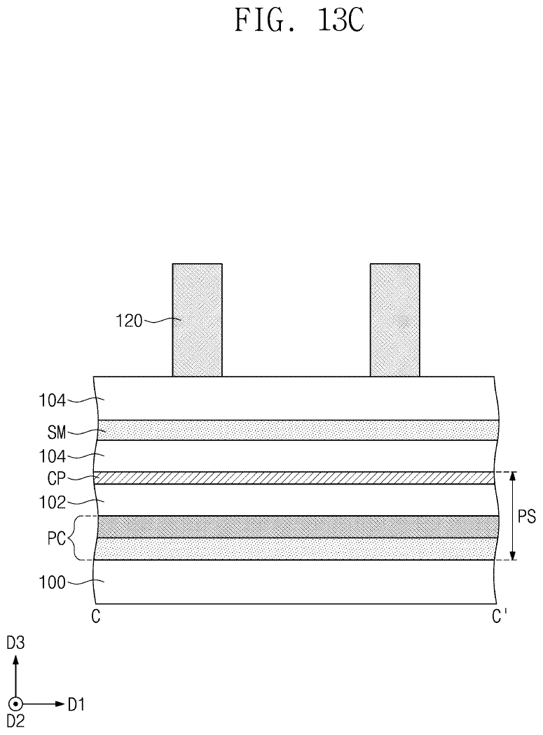

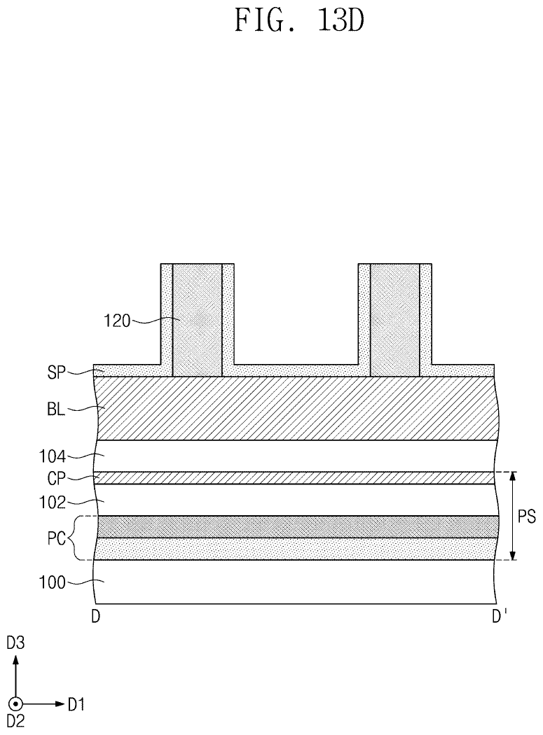

Referring to FIG. 3 and FIGS. 13A to 13D, a semiconductor pattern SP may be formed. Forming the semiconductor pattern SP may include filling the first trenches TR1 with a second mold layer (not shown), removing an upper portion of the first mold layer 122 and the second mold layer to expose a semiconductor layer SL formed on the first insulating pattern 120, removing a portion of the exposed semiconductor layer SL, and removing the remainder of the first mold layer 122 and the second mold layer.

Removing the upper portion of the first mold layer 122 and the second mold layer and removing the portion of the semiconductor layer SL may be performed through a planarization process. The planarization may be performed, for example, through a chemical mechanical polishing (CMP) process or an etch back process. The planarization process may be performed until upper surfaces of the first insulating patterns 120 are exposed.

A plurality of semiconductor patterns SP may be formed by partially removing the semiconductor layer SL.

The second mold layer may include a material including carbon. For example, the second mold layer may include a spin-on hardmask (SOH) and an amorphous carbon layer (ACL).

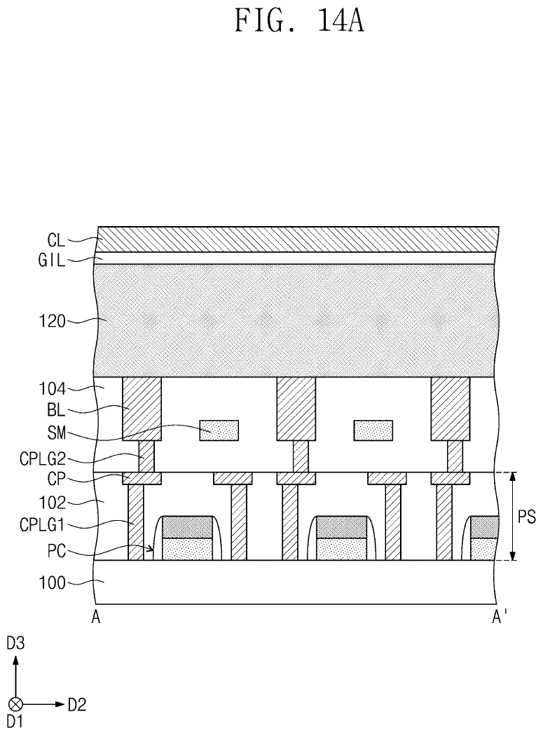

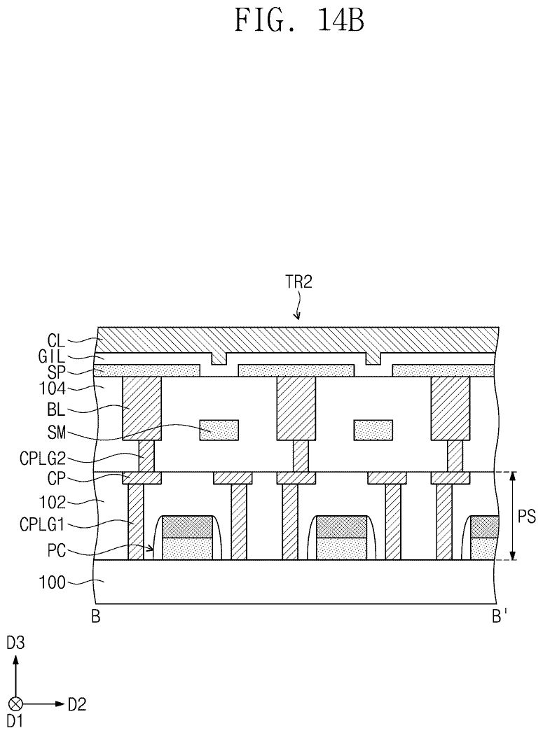

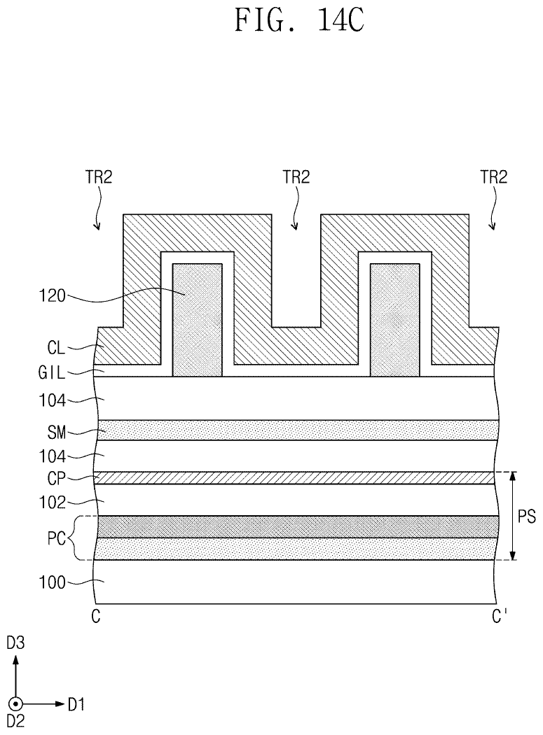

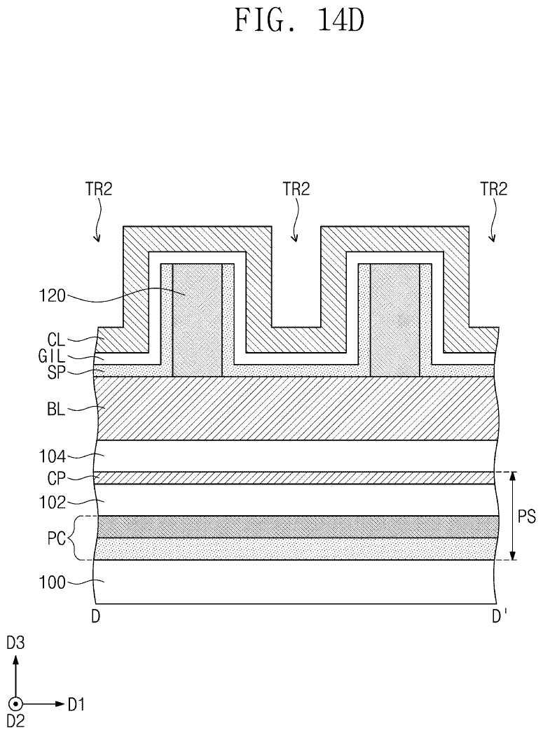

Referring to FIG. 3 and FIGS. 14A to 14D, a gate insulating layer GIL and a conductive layer CL may be formed sequentially. Forming of the gate insulating layer GIL and the conductive layer CL may be formed using a layer-forming technique having excellent step coating properties, such as chemical vapor deposition (CVD), physical vapor deposition (PVD), atomic layer deposition (ALD), etc. The gate insulating layer GIL may conformally cover a side surface and an upper surface of the first insulating pattern 120, the exposed upper surface of the second interlayer insulating layer 104, an upper surface of the semiconductor pattern SP, and the semiconductor patterns SP. The conductive layer CL may conformally cover the gate insulating layer GIL. By conformally forming the gate insulating layer GIL and the conductive layer CL, second trenches TR2 may be formed. The second trenches TR2 may extend in the second direction D2 and be spaced apart from each other in the first direction D1.

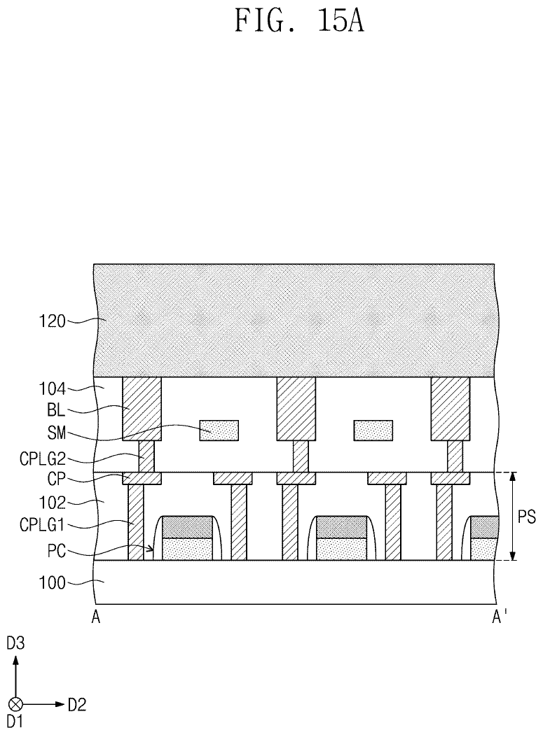

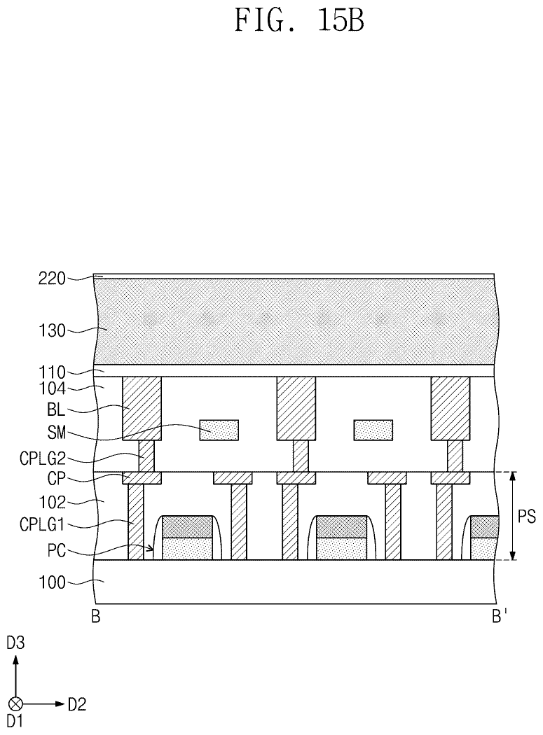

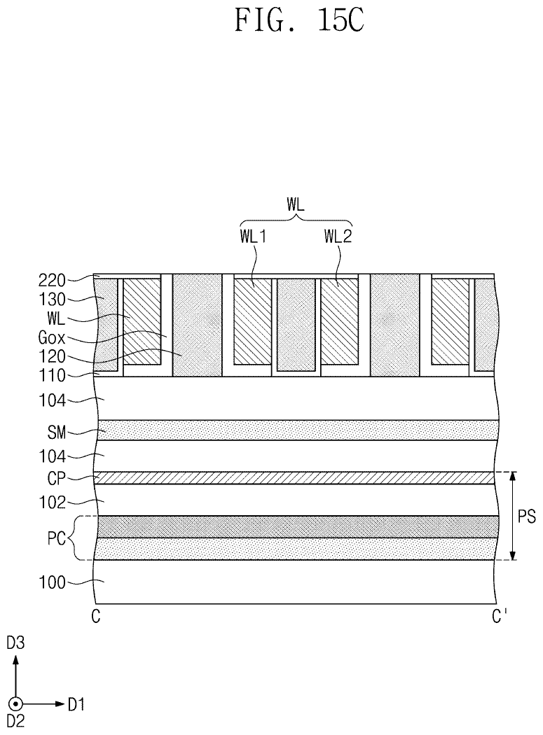

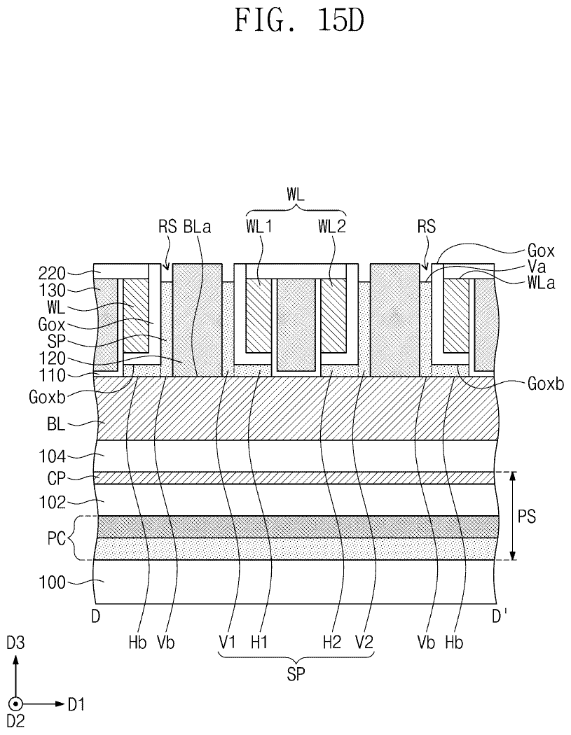

Referring to FIG. 3 and FIGS. 15A to 15D, a word line WL and a gate insulating pattern Gox may be formed. The word line WL may be formed to include a first word line WL1 on the first vertical portion V1 and a second word line WL2 on the second vertical portion V2. Forming the word line WL may include, for example, removing a conductive layer CL on the first insulating pattern 120. In addition, removing a portion of the conductive layer CL vertically overlapping the second trenches TR2 may be further provided to separate the conductive layer CL into a plurality of word lines WL.

When forming the word line WL, a portion of the gate insulating layer GIL may be removed to separate the gate insulating layer GIL into a plurality of gate insulating patterns Gox. That is, the gate insulating layer GIL on the first insulating pattern 120 and the portion vertically overlapping the second trenches TR2 may be removed.

A portion of the semiconductor pattern SP may be removed to separate a portion between the first and second vertical portions V1 and V2 into a first horizontal portion H1 and a second horizontal portion H2. Forming the first horizontal portion H1 and the second horizontal portion H2 may include, for example, removing a portion of the semiconductor pattern SP that vertically overlaps the second trenches TR2.

A protection pattern 110 may be formed along inner surfaces of the word lines WL. Forming the protection pattern 110 may include forming a protection layer (not shown) that conformally covers the inner surfaces of the word lines WL and removing a portion of the protection layer.

Thereafter, a second insulating pattern 130 may be formed between a first word line WL1 and a second word line WL2. Forming the second insulating pattern 130 may include forming a second insulating layer (not shown) on the entire surface of the substrate 100, and removing an upper portion of the second insulating layer to separate the second insulating layer into a plurality of second insulating patterns 130. Upper surface of the second insulating pattern 130 may be formed to be positioned at a lower height than an upper surface Goxa of the gate insulating pattern Gox and an upper surface of the first insulating pattern 120, and at the same height as an upper surface WLa of the word line WL.

A capping pattern 220 may be formed on the upper surface WLa of the word line WL, the upper surface of the protection pattern 110, and the upper surface of the second insulating pattern 130. When the capping pattern 220 is formed, upper surface of the first insulating pattern 120 and upper surfaces Va of the first and second vertical portions V1 and V2 may be exposed to the outside.

Then, a recess RS may be formed on the upper portion of each of the first and second vertical portions V1 and V2. Forming the recesses RS may include, for example, selectively etching upper portions of each of the first and second vertical portions V1 and V2. Due to the recesses RS, the upper surfaces Va of the first and second vertical portions V1 and V2 may be positioned at a lower height than the upper surface WLa of the word line WL.

Referring to FIG. 3 and FIGS. 16A to 16E, a landing conductive layer LCL may be formed on the entire surface of a semiconductor device being manufactured. The landing conductive layer LCL may fill the recesses RS on the upper portions of the first and second vertical portions V1 and V2. The landing conductive layer LCL may include a base layer 300L, a blocking layer 310L, a barrier layer 320L, and a contact layer 330L. The base layer 300L, the blocking layer 310L, the barrier layer 320L, and the contact layer 330L may be sequentially formed on the entire surface of the substrate 100. The base layer 300L may conformally cover the lower surface and the side surface of the recesses RS, and may extend onto the upper surfaces of the gate insulating pattern Gox, the capping pattern 220, and the first insulating pattern 120. The blocking layer 310L may conformally cover the base layer 300L. The barrier layer 320L may conformally cover the blocking layer 310L.

The contact layer 330L may conformally cover the barrier layer 320L. Forming the contact layer 330L may include, for example, chemical vapor deposition (CVD) using a precursor of WF6 and a reducing gas of SiH4 or B2H6. The contact layer 330L may be formed using a precursor of WF6 and a reducing gas of SiH4. When SiH4 is used, a grain size of tungsten (W) forming the contact layer 330L may be reduced. In addition, during the process of forming the contact layer 330L, nitrogen treatment (N treatment) may be performed intermittently. When nitrogen treatment (N treatment) is added, tungsten (W) forming the contact layer 330L may be deposited better, and the grain size of tungsten (W) may also be reduced. Accordingly, the contact layer 330L may include tungsten (W) having a grain size greater than 10 nm and smaller than 40 nm. However, the material forming the contact layer 330L is not limited to tungsten (W).

Referring again to FIGS. 3 to 6 and 7A, landing pads LP may be formed on the first and second vertical portions V1 and V2, respectively. Forming the landing pads LP may include, for example, removing a portion of the landing conductive layer LCL to separate the landing conductive layer LCL into a plurality of landing pads LP.

A third interlayer insulating layer 240 may be formed to fill spaces between the landing pads LP on the first and second insulating patterns 120 and 130. Data storage patterns DSP may be formed on the landing pads LP, respectively. The data storage patterns DSP may be electrically connected to the first and second vertical portions V1 and V2 of the semiconductor pattern SP through the landing pads LP, respectively.

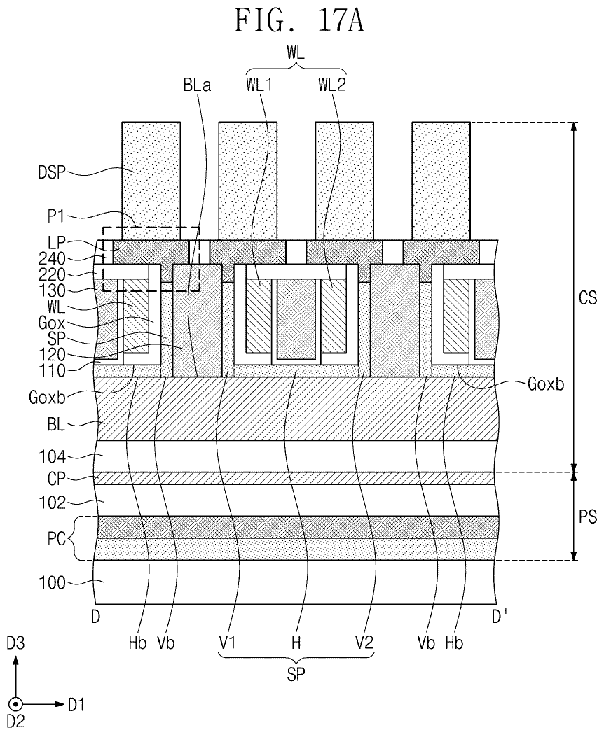

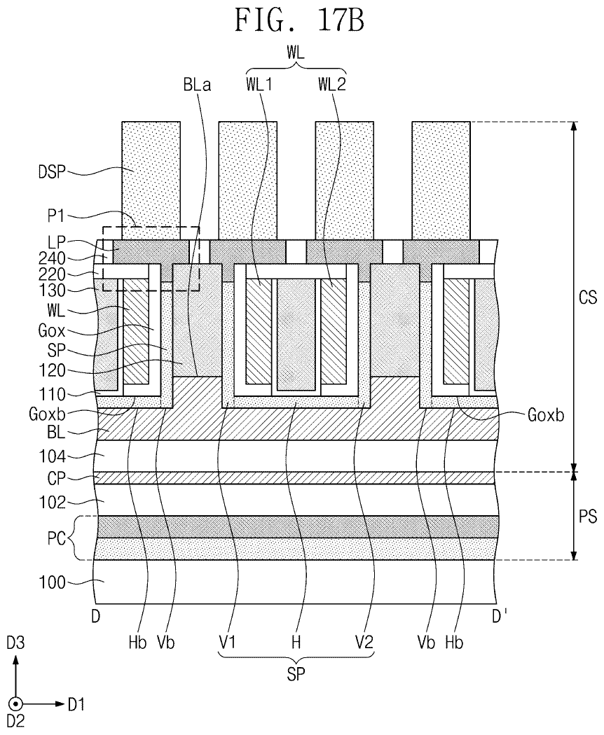

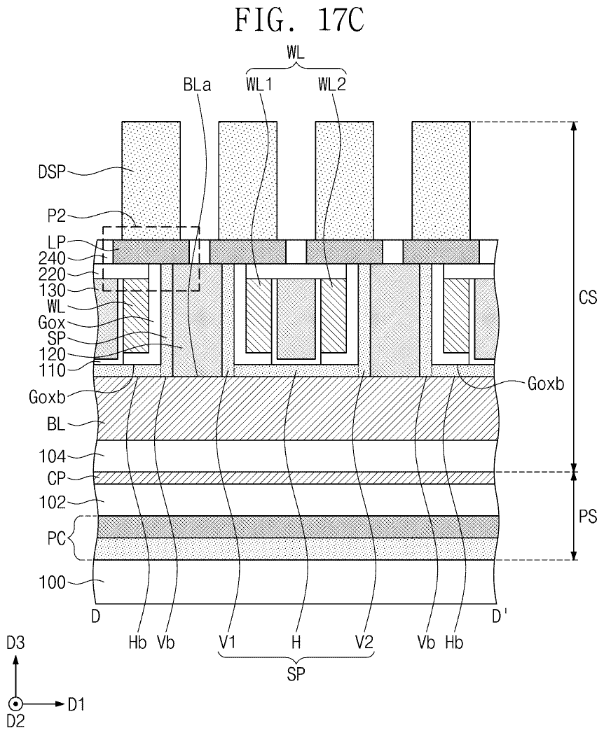

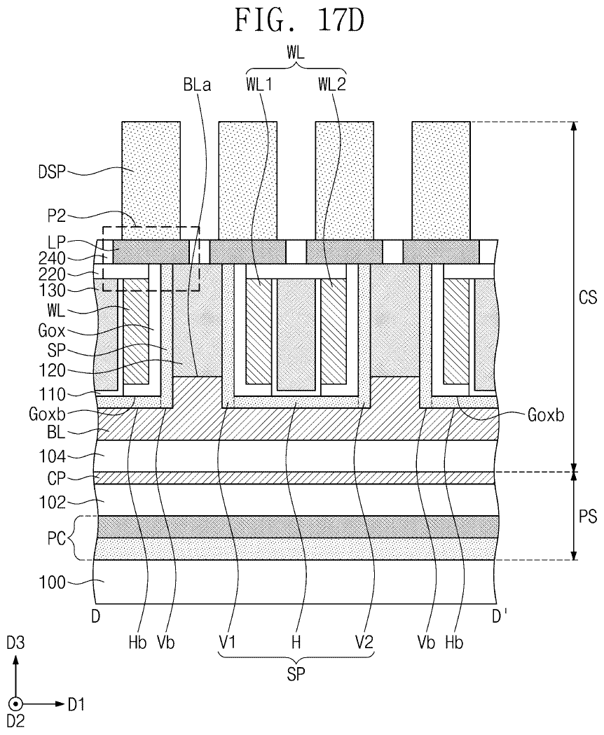

FIGS. 17A to 17D are cross-sectional views of semiconductor devices according to some embodiments of inventive concepts, each corresponding to a line D-D′ of FIG. 3. For simplicity of explanation, any overlapping content with the above description will be omitted.

Referring to FIGS. 17A to 17D, a semiconductor pattern SP may include a first vertical portion V1 and a second vertical portion V2 spaced apart from each other in the first direction D1. In addition, the semiconductor pattern SP may include a horizontal portion H connecting the first and second vertical portions V1 and V2 between the first and second vertical portions V1 and V2. The horizontal portion H may be adjacent to the lower portions of the first and second vertical portions V1 and V2 to connect the first and second vertical portions V1 and V2. The horizontal portion H may be in a form in which the first horizontal portion H1 and the second horizontal portion H2 extend toward each other and form an integral body, as compared to FIGS. 7A to 7D.

The horizontal portion H of the semiconductor pattern SP may be provided on an upper surface of the bit line BL. As an example, referring to FIGS. 17A and 17C, the lower surface Hb of the horizontal portion H may be in contact with the uppermost surface BLa of the bit line BL and may be disposed at the same height as the uppermost surface BLa of the bit line BL. The lower surfaces Vb of the first and second vertical portions V1 and V2 may be in contact with the uppermost surface BLa of the bit line BL and may be positioned at the same height as the uppermost surface BLa of the bit line BL. The lower surfaces Vb of the first and second vertical portions V1 and V2 may be coplanar with the lower surface Hb of the horizontal portion H.

As another example, referring to FIGS. 17B and 17D, the lower surface Hb of the horizontal portion H of the semiconductor pattern SP may be positioned at a lower height than the uppermost surface BLa of the bit line BL. At least a portion of the horizontal portion H may be buried in an upper portion of the bit line BL. An upper surface of the horizontal portion H may be positioned at a lower height than the uppermost surface BLa of the bit line BL, but is not limited thereto. Although not shown, the upper surface of the horizontal portion H may be disposed at a height higher than or equal to the uppermost surface BLa of the bit line BL. The lower surfaces of the first and second vertical portions V1 and V2 may be buried the upper portion of the bit line BL. The lower surfaces Vb of the first and second vertical portions V1 and V2 may be substantially coplanar with the lower surface Hb of the horizontal portion H and may be disposed at a height lower than the uppermost surface BLa of the bit line BL.

As an example, as shown in FIGS. 17A to 17D, the gate insulating patterns Gox may be interposed between the first vertical portion V1 and the first word line WL1, and between the second vertical portion V2 and the second word line WL2, respectively, and may be separated without being connected to each other on the horizontal portion H. That is, the gate insulating patterns Gox may be spaced apart from each other on the horizontal portion H.

As another example, although not shown, the gate insulating pattern Gox may be interposed between the first vertical portion V1 and the first word line WL1, and between the second vertical portion V2 and the second word line WL2, and may extend to be connected on the horizontal portion H.

The enlarged view of portion ‘P1’ of FIGS. 17A and 17B is shown in FIG. 8A. The enlarged view of portion ‘P2’ of FIGS. 17C and 17D is shown in FIG. 8B. That is, the portion ‘P’ of FIGS. 17A and 17B may have substantially the same structure as the portion ‘P1’ of FIGS. 7A and 7B. The portion ‘P2’ of FIGS. 17C and 17D may have substantially the same structure as the portion ‘P2’ of FIGS. 7C and 7D.

According to embodiments of inventive concepts, hydrogen may be limited and/or prevented from diffusing into the channel, and as a result, the electrical characteristics and/or reliability of semiconductor devices according to embodiments of inventive concepts may be improved.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While embodiments are described above, a person skilled in the art may understand that many modifications and variations are made without departing from the spirit and scope of inventive concepts defined in the following claims. Accordingly, the example embodiments of inventive concepts should be considered in all respects as illustrative and not restrictive, with the spirit and scope of inventive concepts being indicated by the appended claims.

What is claimed is:

1. A semiconductor device comprising:
a bit line extending in a first direction;
a first semiconductor vertical portion on the bit line and extending in a vertical direction, the vertical direction being perpendicular to an uppermost surface of the bit line;
a first word line adjacent to the first semiconductor vertical portion;
a gate insulating pattern between the first semiconductor vertical portion and the first word line; and
a contact pattern on an upper surface of the first semiconductor vertical portion, wherein
the upper surface of the first semiconductor vertical portion is at a lower height than an upper surface of the first word line and an upper surface of the gate insulating pattern,
the contact pattern includes metal, and
a grain size of the metal is greater than 10 nm and smaller than 40 nm.

2. The semiconductor device of claim 1, further comprising:
a base pattern between the upper surface of the first semiconductor vertical portion and the contact pattern, wherein
the contact pattern extends onto the upper surface of the gate insulating pattern, and
the base pattern extends between the gate insulating pattern and the contact pattern.

3. The semiconductor device of claim 2, further comprising:
a barrier pattern between the contact pattern and the base pattern.

4. The semiconductor device of claim 3, further comprising:
a blocking pattern between the base pattern and the barrier pattern.

5. The semiconductor device of claim 4, wherein the blocking pattern includes an amorphous metal.

6. The semiconductor device of claim 1, further comprising:
a first semiconductor horizontal portion extending in the first direction from a lower portion of the first semiconductor vertical portion toward a lower portion of the first word line,
wherein the first semiconductor vertical portion and the first semiconductor horizontal portion are connected to each other to form an integral body.

7. The semiconductor device of claim 6, wherein a lower surface of the first semiconductor horizontal portion is positioned at a same height as the uppermost surface of the bit line.

8. The semiconductor device of claim 6, wherein a lower surface of the first semiconductor horizontal portion is positioned at a lower height than the uppermost surface of the bit line.

9. A semiconductor device comprising:
a bit line extending in a first direction;
a first semiconductor vertical portion on the bit line and extending in a vertical direction, the vertical direction being perpendicular to an uppermost surface of the bit line;
a first word line adjacent to the first semiconductor vertical portion;
a gate insulating pattern between the first semiconductor vertical portion and the first word line;
a contact pattern on an upper surface of the first semiconductor vertical portion and extending onto an upper surface of the gate insulating pattern; and
a blocking pattern between an upper surface of the first semiconductor vertical portion and the contact pattern, wherein
the blocking pattern extends between the gate insulating pattern and the contact pattern,
the upper surface of the first semiconductor vertical portion is positioned at a higher height than an upper surface of the first word line and at a same height as an upper surface of the gate insulating pattern, and
the blocking pattern includes an amorphous metal.

10. The semiconductor device of claim 9, wherein
the contact pattern includes metal, and
a grain size of the metal is greater than 10 nm and smaller than 40 nm.

11. The semiconductor device of claim 9, further comprising:
a base pattern between the upper surface of the first semiconductor vertical portion and the blocking pattern, wherein
the base pattern extends between the gate insulating pattern and the blocking pattern.

12. The semiconductor device of claim 10, further comprising:
a barrier pattern between the contact pattern and the blocking pattern.

13. A semiconductor device comprising:
a bit line extending in a first direction;
a semiconductor pattern on the bit line, the semiconductor pattern including a first vertical portion and a second vertical portion spaced apart from each other in the first direction;
a first word line and a second word line spaced apart from each other in the first direction between the first vertical portion and the second vertical portion, the first word line and the second word line being adjacent to the first vertical portion and the second vertical portion, respectively;
gate insulating patterns between the first vertical portion and the first word line, and the gate insulating patterns being between the second vertical portion and the second word line, respectively; and
contact patterns on an upper surface of the first vertical portion and an upper surface of the second vertical portion, respectively,
wherein the upper surface of the first vertical portion and the upper surface of the second vertical portion are positioned at a lower height than an upper surface of the first word line, an upper surface of the second word line, and upper surfaces of the gate insulating patterns, and
each of the contact patterns includes a metal, and
a grain size of the metal is greater than 10 nm and smaller than 40 nm.

14. The semiconductor device of claim 13, further comprising:
base patterns between the contact patterns and gate insulating patterns,
wherein the base patterns extend between the contact patterns and an upper surface of the first vertical portion and between the contact patterns and the upper surface of the second vertical portion, respectively,
wherein the contact patterns extend onto the upper surfaces of the gate insulating patterns, respectively.

15. The semiconductor device of claim 14, further comprising:
barrier patterns between the contact patterns and the base patterns, respectively.

16. The semiconductor device of claim 15, further comprising:
blocking patterns between the base patterns and the barrier patterns, respectively,
wherein each of the blocking patterns includes an amorphous metal.

17. The semiconductor device of claim 13, wherein
the semiconductor pattern further includes a first horizontal portion and a second horizontal portion,
the first horizontal portion extends from a lower portion of the first vertical portion toward the second vertical portion, and
the second horizontal portion extends from a lower portion of the second vertical portion toward the first vertical portion.

18. The semiconductor device of claim 17, wherein a lower surface of the first horizontal portion and a lower surface of the second horizontal portion each are positioned at a same height as an uppermost surface of the bit line.

19. The semiconductor device of claim 17, wherein a lower surface of the first horizontal portion and a lower surface of the second horizontal portion each are positioned at a lower height than an uppermost surface of the bit line.

20. The semiconductor device of claim 17, wherein the first horizontal portion and the second horizontal portion extend toward each other and form an integrated body.
